(19) United States
(12) Patent Application Publication
(10) Pub. No.: US 2014/0097079 A1
(43) Pub. Date: Apr. 10, 2014

(54) FILM FORMING METHOD BY SPUTTERING APPARATUS AND SPUTTERING APPARATUS

(71) Applicant: Canon Anelva Corporation, Kawasaki-shi (JP)

(72) Inventors: Tetsuya ENDO, Kawasaki-shi (JP); Hiroyuki HOSOYA, Kawasaki-shi (JP)

(73) Assignee: Canon Anelva Corporation, Kawasaki-shi (JP)

(21) Appl. No.: 14/098,892

(22) Filed: Dec. 6, 2013

Related U.S. Application Data
(62) Division of application No. 13/446,015, filed on Apr. 13, 2012.
Application No. 13/446,015 is a continuation of application No. PCT/JP2010/065524, filed on Sep. 9, 2010.

(30) Foreign Application Priority Data
Nov. 10, 2009 (JP) 2009-256919

(51) Int. Cl. C23C 14/35

(52) U.S. Cl. CPC C23C 14/35
USPC 204/192.12

(57) ABSTRACT

The present invention provides a film forming method which can reduce deterioration of film thickness distribution even if the thickness of a film to be formed is extremely small while improving use efficiency of a target and a sputtering apparatus. A film forming method by a sputtering apparatus according to one embodiment of the present invention has a first step of fixing a magnet to a first position and performing film formation on a substrate on a substrate support surface, a second step of moving the magnet to a second position different from the first position after finishing the film formation on the substrate and then fixing it thereto, and a third step of performing film formation on the substrate on the substrate support surface by using the magnet fixed to the second position.

### CROSS-REFERENCES TO RELATED APPLICATIONS

This application is a continuation application of International Application No. PCT/JP2010/065524, filed Sep. 9, 2010, which claims the benefit of Japanese Patent Application No. 2009-256919, filed Nov. 10, 2009. The contents of the aforementioned applications are incorporated herein by reference in their entireties.

### TECHNICAL FIELD

The present invention relates to a film forming method by a sputtering apparatus and a sputtering apparatus.

### BACKGROUND ART

A magnetoresistance effect type magnetic head mounted on a magnetic recording/reproducing apparatus or a so-called hard disk drive makes reproduced output by using a phenomenon in which electric resistance is changed in accordance with an angle formed by magnetization of a fixed layer and a free layer. As a method of reducing a noise in this reproduced output, there is a method of arranging a hard-bias structure laminated body on both sides of the magnetoresistance effect laminated body (See Patent Document 1). Uniaxial anisotropy, that is, formation of a single magnetic domain is promoted in the free layer by the hard-bias structure, and noise reduction can be realized. On the other hand, in order to obtain linear response to a magnetic field from the magnetic recording medium, an anisotropy magnetic field of the free layer by the formation of the single magnetic domain is preferably increased.

Regarding provision of the magnetic anisotropy to the free layer in the magnetoresistance effect type magnetic head, oblique incident film formation in the film formation of a magnetic film of interest is proposed (See Patent Document 2). Patent Document 2 describes that a single magnetic domain state can be obtained by applying oblique incident film formation to form the free layer without having a laminated body for giving a vertical bias magnetic field, and reproducing properties with high reproducing sensitivity and low noise can be realized even if narrowing of a track width proceeds.

On the other hand, the oblique incident sputtering for giving anisotropy to a magnetic film is possible by a method in which a substrate passes through a target front face on which the sputtering operation is performed (hereinafter referred to as “passing film formation”) (See Patent Documents 3 and 4).

In the case of the passing film formation, in order to obtain favorable film thickness distribution, among respective sides of a target, the longer the side is in a traveling (movement) direction of the substrate and the side in a direction parallel to the traveling direction may be short. Therefore, a rectangular type sputtering target is often used. For example, in the case of film formation on a substrate with a diameter of 200 mm, a rectangular target having a length in the perpendicular direction of 450 to 600 mm and the length in the parallel direction of 100 to 150 mm to the traveling direction of the substrate is used.

A rectangular magnet is used for a rectangular target, and the magnet is oscillated/reciprocally moved with respect to target position for the purpose of improvement for target use efficiency or reduction of a non-sputtered region in most of the cases. However, when the rectangular magnet is oscillated, improvement of an oscillation cycle (reciprocating cycle) is practically difficult since the center of gravity of a cathode fluctuates all the time and it causes mechanical instability, and the oscillation cycle is approximately several Hz at the most.

In such circumstances, if a film having a film thickness of several tens Å such as a free layer of a magnetoresistance effect type laminated body is to be formed by a passing sputtering apparatus, a magnet reciprocating cycle per film-forming time of a single layer is within 10 cycles at the most. Since the film forming time is short and the number of times of reciprocating is small, a sputter source shape is transferred onto the substrate. Here, the sputter source refers to a region where sputter is generated on the target.

A measure to satisfy the film thickness distribution and target use efficiency by optimizing the oscillating motion (cycle) of the rectangular target and a cathode magnet has been already proposed (See Patent Documents 5 and 6).

Patent Document 5 describes a film forming method in which a speed of a magnet in the substrate moving direction in a cathode magnet making an oscillating motion is 1/10 or less of a moving speed of the substrate and 150 mm/minute or more and a speed of reciprocating movement in a direction perpendicular to the substrate moving direction is set to the size that 0.3 sessions or more of reciprocating are made while the substrate moves 100 mm while facing the surface of the target. Moreover, Patent Document 5 describes that by setting the oscillating speed in a direction perpendicular to the substrate conveying direction faster than the moving speed in the substrate conveying direction, a probability that a magnetic force line formed by the magnet passes the same spot on the target surface is lowered, a biased sputtered portion where a specific spot on the target is sputtered more than the other spots becomes small, and a non-erosion portion is considerably decreased. According to the film forming method of Patent Document 5, since the non-erosion portion can be reduced, occurrence of particles can be suppressed, occurrence of nodule can be also suppressed, and occurrence of abnormal discharge can be reduced. The biased sputtering can be improved, and use efficiency of a target is improved.

On the other hand, Patent Document 7 describes a sputtering apparatus provided with slit means for selecting sputtered particles and having a small difference between the width in the substrate traveling direction of the magnet and the substrate size. The sputtering apparatus described in Patent Document 7 will be described by using FIGS. 14A to 16.

FIG. 14A is a side view of a sputtering apparatus 1600 according to Patent Document 7. FIG. 14B is a perspective view of the sputtering apparatus 1600 according to Patent Document 7.

In FIGS. 14A and 14B, the sputtering apparatus 1600 includes a stage 1601 on which a substrate 1604 is mounted, a cathode 1602 supporting a target 1603, and a shield plate 1606, and a target support surface of the cathode 1602 and a substrate support surface of the stage 1601 are arranged so as to face each other. The stage 1601 and the cathode 1602 include a rotating shaft A and a rotating shaft B, respectively, and the stage 1601 and the cathode 1602 are rotatable by arbitrary angles around the rotating shaft A and the rotating shaft B, respectively. For example, the stage 1601 and the cathode 1602 can be rotated by using rotating means such as a motor, and this rotating means can be controlled by a controller.

The rotating shaft A and the rotating shaft B are arranged in parallel with each other, and the cathode 1602 can support the target 1603 so that the target 1603 is in parallel with the rotating shaft B. The target 1603 supported by the cathode 1602 rotatable by an arbitrary angle around the rotating shaft B can deposit sputtered particles 1605 on the substrate 1604 by making ions in plasma collide against the surface of the target 1603 in either of during stop or during rotation.

During film formation processing, the substrate 1604 subjected to the film formation processing by the target 1603 is placed on the stage 1601 rotatable by an arbitrary angle around the rotating shaft A. The substrate support surface of the stage 1601 and the target support surface of the cathode 1602 are independently configured rotatably around the rotating shaft A and the rotating shaft B, respectively.

Moreover, the shield plate 1606 is provided between the target 1603 and the stage 1601. The shield plate 1606 has means for rotating by an arbitrary angle around either of the rotating shaft A or the rotating shaft B and serves a function of improving fine adjustment of film thickness distribution of a film to be deposited and selectability of an incident angle of sputtered particles. The shield plate 1606 can rotate around the rotating shaft A or the rotating shaft B by an arbitrary method but is configured rotatable around the rotating shaft A in the configuration described below. The shield plate 1606 can be controlled by a controller so as to make a rotary motion independently of the cathode 1603 or the stage 1601.

FIG. 15A is a side view of a stage 1701 usable as a stage for the sputtering apparatus in FIG. 14A. The stage 1701 has a substrate placing table 1702, and a substrate 1703 is placed on the substrate placing table 1702. FIG. 15B is a perspective view of the stage 1701 according to Patent Document 7. The stage 1701 is configured rotatable around the rotating shaft A as in FIG. 14. The substrate placing table 1702 of the stage 1701 is perpendicular to the rotating shaft A and also is configured rotatable around a rotating shaft C passing through the center of the substrate 1703 and is capable of rotating the substrate 1703 around the rotating shaft C. The substrate placing table 1702 can be rotated by using rotating means such as a motor, for example, and this rotating means can be controlled by a controller.

FIG. 16 is a view illustrating an example of another sputtering apparatus described in Patent Document 7. A sputtering apparatus 1800 includes a stage 1801 on which a substrate 1804 is placed, a cathode 1802 supporting targets 1803a to 1803c, and a shied plate 1805. The stage 1801 and the cathode 1802 include the rotating shaft A and the rotating shaft B, respectively, and at least one of the stage 1801 and the cathode 1802 is configured to rotate by an arbitrary angle around the rotating shaft A and the rotating shaft B. For example, at least one of the stage 1801 and the cathode 1802 can be rotated by using rotating means such as a motor, and the rotating means can be controlled by a controller. The rotating shaft A and the rotating shaft B are arranged in parallel with each other, and the targets 1803a to 1803c are supported by the cathode 1802 so as to be parallel with respect to the rotating shaft B.

The targets 1803a to 1803c supported by the cathode 1802 rotatable by an arbitrary angle around the rotating shaft B can deposit sputtered particles on the substrate 1804 by making ions in plasma collide against the target surfaces in both during stop and during rotation.

The substrate 1804 subjected to the film formation processing by the targets 1803a to 1803c is placed on the stage 1801 rotatable by an arbitrary angle around the rotating shaft A. The stage 1801 has a substrate placing table 1807, and the substrate 1804 can be provided on the substrate placing table 1807. The substrate placing table 1807 of the stage 1801 is perpendicular to the rotating shaft A and also is configured rotatable around a rotating shaft (not shown) passing through the center of the substrate 1804 and can rotate the substrate 1804 around the rotating shaft. The substrate placing table 1807 can be rotated by using rotating means such as a motor, for example, and this rotating means can be controlled by a controller.

Moreover, a shield plate 1805 is provided between the target and the stage 1801, and the shield plate 1805 has means for rotating by an arbitrary angle around the rotating shaft A and serves a function of improving fine adjustment of film thickness distribution of a film to be deposited and selectability of an incident angle of sputtered particles. The shield plate 1805 can rotate around the rotating shaft A independently of the cathode 1802 or the stage 1801 by appropriately controlling rotating means 1806 for shield plate by a controller.

Usually, a film with improved orientation has a plurality of layers, and its typical examples are Ta/FeCo, NiFe/FeCo, and NiFeCr/FeCo. In order to manufacture such a film a plurality of layers, it is preferable that the target 1803 supported by the cathode 1802 is provided in plural. In the mode of FIG. 16, a plurality of targets 1803a, 1803b, and 1803c are present, and the targets 1803a, 1803b, and 1803c can be used in accordance with use applications as appropriate. The rotating shaft A and the rotating shaft B are arranged in parallel with each other, and the targets 1803a, 1803b, and 1803c are supported by the cathode 1802 so that they are in parallel with the rotating shaft B. The targets 1803a, 1803b, and 1803c rotatable around the rotating shaft B deposit the sputtered particles on the substrate 804 by making the ions in plasma collide against the surface of the target 1803.

### CITATION LIST

### Patent Document

[Patent Document 1] U.S. Pat. No. 7,061,731
[Patent Document 2] Japanese Patent Application Laid-open No. 2007-200428
[Patent Document 3] Japanese Patent Application Laid-open No. 2007-525005 (Translation of PCT)
[Patent Document 4] Japanese Patent Application Laid-open No. 07-54145
[Patent Document 5] Japanese Patent Application Laid-open No. 2009-46730
[Patent Document 6] Japanese Patent Application Laid-open No. 10-46334
[Patent Document 7] WO2009/028055

### SUMMARY OF INVENTION

However, with the sputtering apparatus described in Patent Document 5, there is no means for shielding sputtered particles between the substrate and the target. With such apparatus configuration, such a problem occurs that anisotropy or the like cannot be given to a film by aligning the incident angle of the sputtered particles. In addition, since a difference between the target (width in the substrate traveling direction) and the substrate size is large, there is a defect that time until a film is formed on the whole surface of the substrate becomes long. On the other hand, with the sputtering apparatus described in Patent Document 7 in which a difference between the magnet (width in the substrate traveling direction) and the substrate size is small, time until the film is formed on the whole surface of the substrate can be reduced, and the number of substrates processed per time can be increased.

However, even if the shield plate 1805 (distribution correcting plate) is present between the substrate 1804 and a region where sputter occurs on the target 1803 (hereinafter referred to as a “sputter source), the following problem occurs. This problem will be described on the basis of FIGS. 17A and 17B. FIGS. 17A and 17B are side views in which a slit is provided in the shield plate of the sputtering apparatus described in FIG. 16 and an oscillating magnet is provided in the cathode. In FIGS. 17A and 17B, an arrow F is an original particle orbit, an arrow C is an orbit deviated by oscillation, a region D is an arbitrary region, and an arrow P is movement of the sputter source (movement of the plasma) caused by the magnet oscillation.

The shield plate 5 is to make sputtered particles flying from a specific angle or a specific region selectively adhere to a substrate W, and within film formation time, the larger the number of reciprocating motions of the sputter source caused by the reciprocating motion of the magnet 7 is, the more averaged a positional relationship between the shield plate 5 and the sputter source with respect to the substrate W becomes by the long reciprocating motion of the sputter source. An example in which sputtered particles having an incident angle in the vicinity of 60° with respect to the normal direction of the substrate W are selectively made to enter to form a film, for example, will be described. In the case of a reciprocating motion cycle of the magnet 7 at 1 Hz (1/s), if the film formation time lasts 50 seconds or more, the reciprocating motion is made 50 times, and the film thickness distribution is averaged. However, if the number of reciprocation is decreasing, the reciprocating motion is made 10 times in the film formation time of approximately 10 seconds, for example, and a problem arises that distribution occurs in the substrate passing direction.

Moreover, in the sputtering apparatus in FIGS. 17A and 17B, the magnet 7 oscillates and performs film forming with rotation of the stage 2. Thus, the sputtered particles generated from the sputter source reach the film-formation target substrate W through the slit 8, but if the position of the sputter source by the oscillation of the magnet 7 forms a relationship as illustrated in FIG. 17A, the sputtered particles deviate from their original orbit F and might take an orbit C of the sputtered particles which does not reach the substrate W.

If the rotation angular speed of the stage 2 is extremely low with respect to the oscillation cycle of the magnet 7, that is specifically, if the oscillation cycle of the magnet 7 is 1 Hz and the rotation angle of the stage 2 is 0.1 degree/second, the oscillation cycle of the magnet 7 is faster than the rotation angular speed of the stage 2, and thus, the sputtered particles might take the orbit C but might take the target orbit F in some cases, and deterioration of film thickness distribution or the like does not occur. In addition, consider the case in which the rotation angular speed of the stage 2 is low, for example the case in which film thickness control is needed with the rotation angular speed of 0.1 degree/second. In such a case, the film formation rate needs to be lowered, and this is usually handled by lowering electricity for sputtering. However, if the electricity for sputtering cannot be lowered due to characteristics/specification of a sputter power source, the rotation angular speed of the stage 2 should be increased. If the rotation angular speed of the stage 2 is increased, a problem occurs that few sputtered particles fly in a region D during a period from FIG. 17A to FIG. 17B.

Such a problem can be solved by quickening the oscillation cycle of the magnet 7 and by reducing a reciprocating cycle (oscillation cycle) of the sputter source, but as already described, if a rectangular magnet is oscillated, the center of gravity of the cathode 4 is fluctuated all the time, and realization is difficult due to instability of the mechanism. On the other hand, fluctuation of the film thickness distribution on the film-formation substrate W can be reduced by not performing the reciprocating motion of the magnet 7 and by stopping the sputter source. However, only with this method, since the sputter source is stopped for the targets 3a, 3b, and 3c, a non-erosion area is generated, and use efficiency of the targets 3a, 3b, and 3c is extremely lowered, which is another problem.

The present invention was made in order to solve the above problems and has an object to provide a film forming method by a sputtering apparatus and a sputtering apparatus which can improve use efficiency of a target and can reduce deterioration of the film thickness distribution even if the film thickness of a film to be formed is extremely small.

The inventor has made examinations in order to solve the above problems and has found out that the film thickness distribution and sheet resistance distribution can be improved by reviewing the moving speed of the substrate and the oscillation cycle of the magnet.

In order to achieve the above-described object, the present invention is a film forming method for performing film formation by causing sputtered particles to enter a substrate at a desired incident angle with a shield plate which supports a sputtering target and which is provided between a cathode having a magnet therein and a stage supporting the substrate, the method comprising: a first step of relatively changing the position of the stage and the position of the cathode to perform the film formation on the substrate, while fixing the magnet to a first position in the cathode to keep the magnet still with respect to the sputtering target; a second step of moving the magnet to a second position different from the first position in the cathode; and a third step of relatively changing the position of the stage and the position of the cathode to perform the film formation on the substrate, while fixing the magnet to the second position to keep the magnet still with respect to the sputtering target.

Moreover, the present invention is a film forming method for performing film formation by causing sputtered particles to enter a substrate at a desired incident angle with a shield plate which supports a sputtering target and which is provided between a cathode having a magnet therein and a stage, while moving the stage that supports the substrate and conveying the substrate, the method comprising: a first step of performing film formation while displacing the magnet in a first direction and displacing at least one of the shield plate and the stage so as to produce a displacement in the first direction, the first step synchronizing start of displacement of the magnet with start of displacement of at least one of the shield plate and the stage; and a second step of synchronizing end of the displacement of the magnet with end of the displacement of at least one of the shield plate and the stage to finish the film formation.

Moreover, the present invention is a sputtering apparatus including: a cathode having a sputtering target support surface; a stage having a substrate support surface; a shield plate disposed between the sputtering support surface and the substrate support surface; a magnet disposed in the cathode and movable in a plane parallel with the target support surface; and a control mechanism which, when a substrate is supported by the substrate support surface, a sputtering target is supported by the sputtering target support surface, and film formation is to be performed on the substrate, controls the magnet so as to keep the magnet still with respect to the supported sputtering target during the film formation, and controls the magnet so as to move the magnet to another position different from the position where the magnet is disposed in the cathode during predetermined film formation between the predetermined film formation and film formation subsequent to the predetermined film formation.

Furthermore, the present invention is a sputtering apparatus including: a cathode having a sputtering target support surface; a stage having a substrate support surface; a shield plate disposed between the sputtering support surface and the substrate support surface; a magnet disposed in the cathode and movable in a plane parallel with the target support surface; and a control mechanism which, when a substrate is supported by the substrate support surface, a sputtering target is supported by the sputtering target support surface, and film formation is to be performed on the substrate, controls at least one of the magnet, the shield plate, and the stage so as to synchronize start of first displacement when displacing the magnet in a first direction with start of second displacement when displacing at least one of the shield plate and the stage so as to produce a displacement in the first direction, and synchronize end of the first displacement of the magnet with end of the second displacement of at least one of the shield plate and the stage.

By using the film forming method by the sputtering apparatus and the sputtering apparatus according to this invention, film thickness distribution can be made uniform even under a condition of short film formation time and a non-erosion region can be eliminated or occurrence of the non-erosion region can be reduced.

### BRIEF DESCRIPTION OF THE DRAWINGS

FIG. 1A is a side view illustrating an example of an operation by a sputtering apparatus according to an embodiment of the present invention.

FIG. 1B is a side view illustrating an example of an operation by the sputtering apparatus according to an embodiment of the present invention.

FIG. 2 is a perspective view illustrating a dimension relationship between a target and a cathode magnet according to an embodiment of the present invention.

FIG. 3A is an outline side view of the sputtering apparatus according to an embodiment of the present invention.

FIG. 3B is an outline side view of the sputtering apparatus according to an embodiment of the present invention.

FIG. 4 is a perspective view illustrating a dimension relationship between the target and the cathode magnet according to an embodiment of the present invention.

FIG. 5 is a perspective view illustrating a dimension relationship of a shield plate according to an embodiment of the present invention.

FIG. 6 is a side view illustrating an example of a film forming method by the sputtering apparatus according to an embodiment of the present invention.

FIG. 7 is a diagram illustrating reciprocal motion/oscillation of the cathode magnet according to an embodiment of the present invention.

FIG. 8A is a diagram illustrating the size of surface resistance distribution per unit area of a thin film formed on a substrate by a prior-art film forming method.

FIG. 8B is a diagram illustrating the size of surface resistance distribution per unit area of a thin film formed on a substrate by the film forming method according to an embodiment of the present invention.

FIG. 9A is a diagram illustrating the size of surface resistance distribution per unit area of a thin film formed on a substrate by a prior-art film forming method.

FIG. 9B is a diagram illustrating the size of surface resistance distribution per unit area of a thin film formed on a substrate by the film forming method according to an embodiment of the present invention.

FIG. 10 is a diagram illustrating a fixed position of a magnet according to an embodiment of the present invention.

FIG. 11A is a side view illustrating motions of the magnet and a stage according to an embodiment of the present invention.

FIG. 11B is a side view illustrating motions of the magnet and the stage according to an embodiment of the present invention.

FIG. 11C is a side view illustrating motions of the magnet and the stage according to an embodiment of the present invention.

FIG. 11D is a side view illustrating motions of the magnet and the stage according to an embodiment of the present invention.

FIG. 12A is a diagram illustrating motion positions of the magnet and the stage according to an embodiment of the present invention.

FIG. 12B is a diagram illustrating motion positions of the magnet and the stage according to an embodiment of the present invention.

FIG. 13 is a block diagram illustrating an outline configuration of a control mechanism in the sputtering apparatus according to an embodiment of the present invention.

FIG. 14A is a side view of a prior-art sputtering apparatus.

FIG. 14B is a perspective view of a prior-art sputtering apparatus.

FIG. 15A is a side view of a stage usable as a stage of the sputtering apparatus in FIG. 14A.

FIG. 15B is a perspective view of a stage of the prior-art sputtering apparatus.

FIG. 16 is a diagram illustrating an example of the prior art sputtering apparatus.

FIG. 17A is a side view illustrating motions of a magnet and a stage of the prior-art film forming method.

FIG. 17B is a side view illustrating motions of the magnet and the stage of the prior-art film forming method.

### DESCRIPTION OF EMBODIMENTS

Embodiments of the present invention will be described below by referring to the attached drawings. In the drawings described below, those having the same functions are assigned the same reference numerals, and duplicated description will be omitted.

### First Embodiment

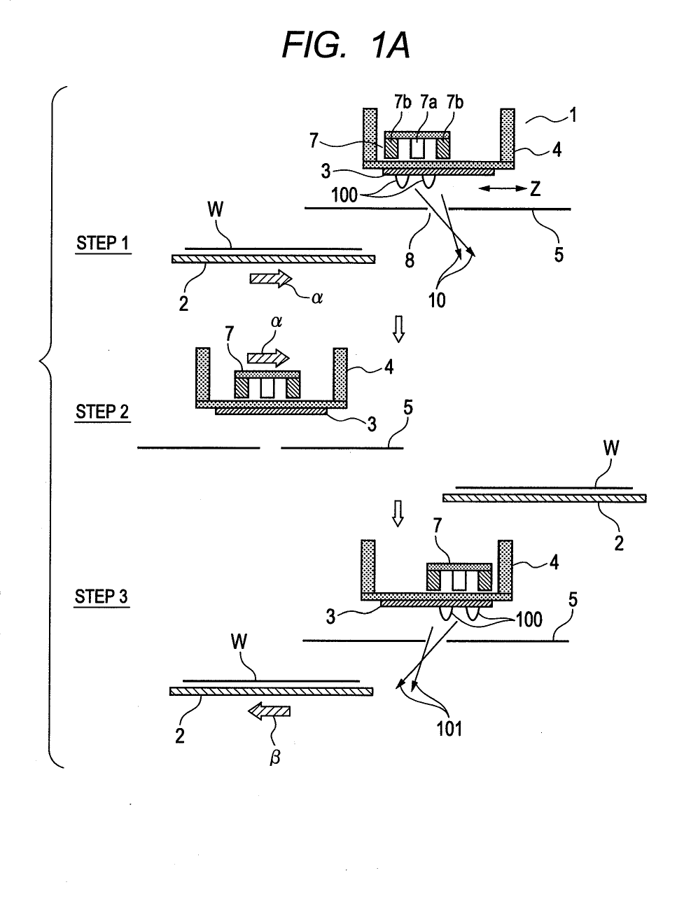

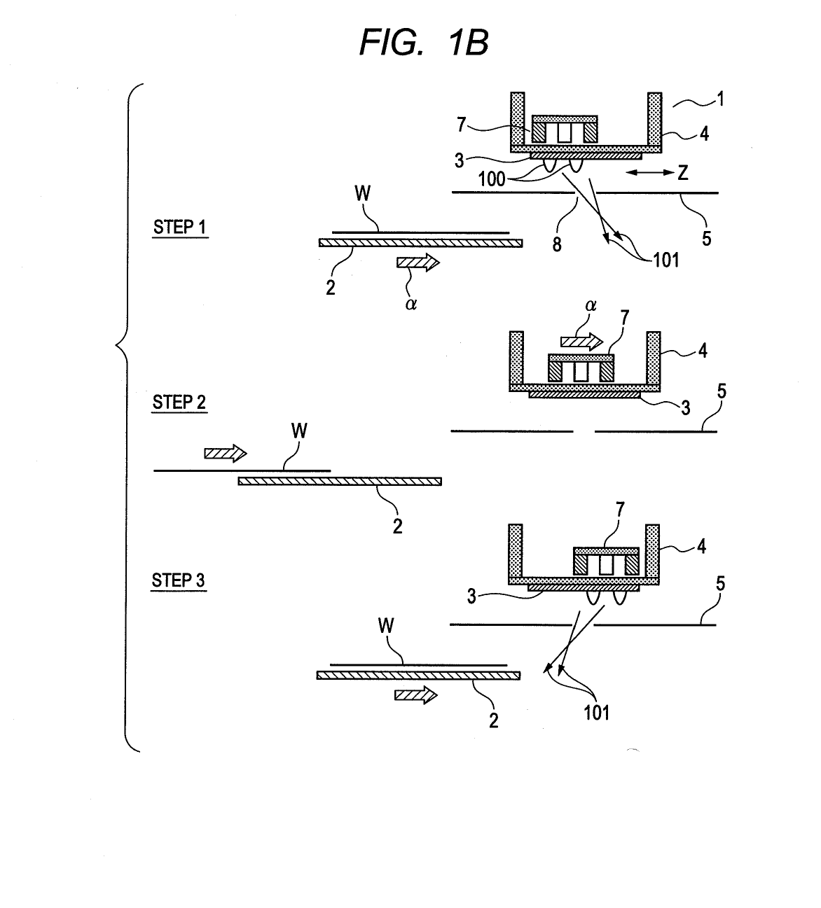

A step 1 to a step 3 in FIG. 1A are side views illustrating an example of an operation by a sputtering apparatus according to the present invention. In FIGS. 1A and 1B, the sputtering apparatus 1 includes a stage 2 as a substrate holding portion on which a substrate W can be placed, a cathode 4 capable of supporting a target 3, and a shield plate 5 having a slit-shaped opening portion (also referred to as a “slit”) 8. In FIG. 1A, the surface of the target 3 (sputter surface) and a substrate placing surface of the stage 2 are substantially parallel with each other. Therefore, the conveying direction Z can be considered as a conveying direction of the substrate when a processed surface of the substrate W (the substrate placing surface of the stage 2) and the surface of the target 3 are substantially parallel with each other.

A cathode magnet 7 is located within the cathode 4 and can move parallel with respect to the surface of the target 3 by means of a magnet driving mechanism, not shown. That is, the cathode magnet 7 includes the magnet driving mechanism, not shown, and is capable of oscillation in the conveying direction Z of the substrate by means of driving of the magnet driving mechanism. The cathode magnet 7 may be oscillated in a direction other than the conveying direction Z (a direction X perpendicular to the conveying direction Z in the plane of the target 3, for example). The magnet driving mechanism, not shown, is controlled by a controller 1000 (not shown in FIGS. 1A and 1B), which will be described later. That is, the cathode magnet 7 has its operation direction, speed, positioning and the like arbitrarily controlled by the controller 1000. The control also includes a stand-still operation.

The cathode magnet 7 has a first magnet 7a having one of polarities (N-pole, for example) and a second substantially rectangular magnet having the other polarity (S-pole, for example) arranged so as to surround the first magnet 7a and so as not to be in contact with each other. In the magnetic field generated on the target 3 by such arrangement, a collection of regions where perpendicular components with respect to the target support surface of the cathode 3, of a magnetic tunnel generated between the first magnet 7a and the second substantially rectangular magnet 7b are substantially corresponds to an erosion track. Since sputters are generated in the erosion track, a sputter source 100 is generated along the erosion track, and sputtered particles 101 are generated from the sputter source 100.

The stage 2 on which the substrate W can be placed is placed facing the surface of the target 3, and in the mode illustrated in FIGS. 1A and 1B, it is configured movable in the conveying direction Z. That is, the stage 2 includes a stage driving mechanism, not shown, and is movable in the conveying direction Z by driving of the stage driving mechanism. Regarding the stage 2, too, the opposite side of the target 3 can be controlled with respect to movement in an arbitrary direction (the conveying direction Z, for example), speed and positioning by the stage driving mechanism, not shown, and the controller 1000 (not shown in FIG. 1A).

The shield plate 5 having the slit-shaped opening portion 8 formed so that the sputtered particles can pass therethrough is placed between the stage 2 and the target 3, and in the mode illustrated in FIGS. 1A and 1B, it is configured movably in the conveying direction Z. That is, the shield plate 5 includes a shield-plate driving mechanism, not shown, and is movable in the conveying direction Z by driving of the shield-plate driving mechanism. The shield plate 5 can be also controlled with respect to an arbitrary moving direction (the conveying direction Z, for example), speed, and positioning between the stage 2 and the target 3 by means of the shield-plate driving mechanism, not shown, and the controller 1000 (not shown in FIGS. 1A and 1B) and plays a function of improving fine adjustment of film thickness distribution of a deposited film and selectivity of an incident angle of a sputter particle. The control of the stage 2 and the shield plate 5 also includes a stand-still operation.

The target 3 supported by the cathode 4 can have the sputtered particles deposited on the substrate W by making ions in plasma collide against the target 3 surface in any case during operations of the cathode magnet 7, the stage 2, and the shield plate 5. Moreover, the control of the cathode magnet 7, the stage 2, and the shield plate 5 can be made by the controller 1000, for example, independently from each other or in conjunction, whereby adjustment for making film thickness distribution on the substrate W and film characteristics uniform is facilitated. The sputtering target 3 has a rectangular shape, and the length in the direction X perpendicular to the conveying direction (conveying direction Z) of the substrate W is longer than the length of the parallel direction Y.

An example of the sputtering apparatus according to this embodiment will be described by using FIG. 1A.

The step 1 in FIG. 1A illustrates a state in which the stage 2 on which the substrate W is placed passes through the opposite surface of the target 3 during the sputtering operation (outward path). The sputtering operation is being performed in a state in which the cathode magnet 7 stands still with respect to the target 3 (cathode 4). Only the sputtered particles having passed through the slit 8 provided in the shield plate 5 contribute to film formation on the substrate W. At this time, if the cathode magnet 7 stands still with respect to the cathode 4, the cathode 4 may be in the stand-still state or may be moved in a predetermined direction. Moreover, the shield plate 5 may be also in the stand-still state during the sputter operation or may be moved in the predetermined direction.

That is, in the step 1 in FIG. 1A, the controller 1000 controls the magnet driving mechanism and positions the cathode magnet 7 at a first position in the cathode 4 and makes it stand still with respect to the cathode 4. Subsequently, when the substrate W is placed on the stage 2, the controller 1000 supplies predetermined power to the cathode 4 to generate plasma and has the sputter source 100 generated and generates the sputtered particles 101. Then, the controller 1000 controls the stage driving mechanism and moves the stage 2 in a direction α in parallel with the conveying direction Z. Therefore, if the stage 2 is entering the region where the stage 2 opposes the opening portion 8, the sputtered particles 101 having passed the opening portion 8 among the sputtered particles 101 generated from the sputter source 100 reach the substrate W, and a predetermined film is formed. In this embodiment, since the opening portion 8 is provided in the shield plate 5, the largest quantity of the sputtered particles having an incident angle within a desired range can made to reach the substrate W.

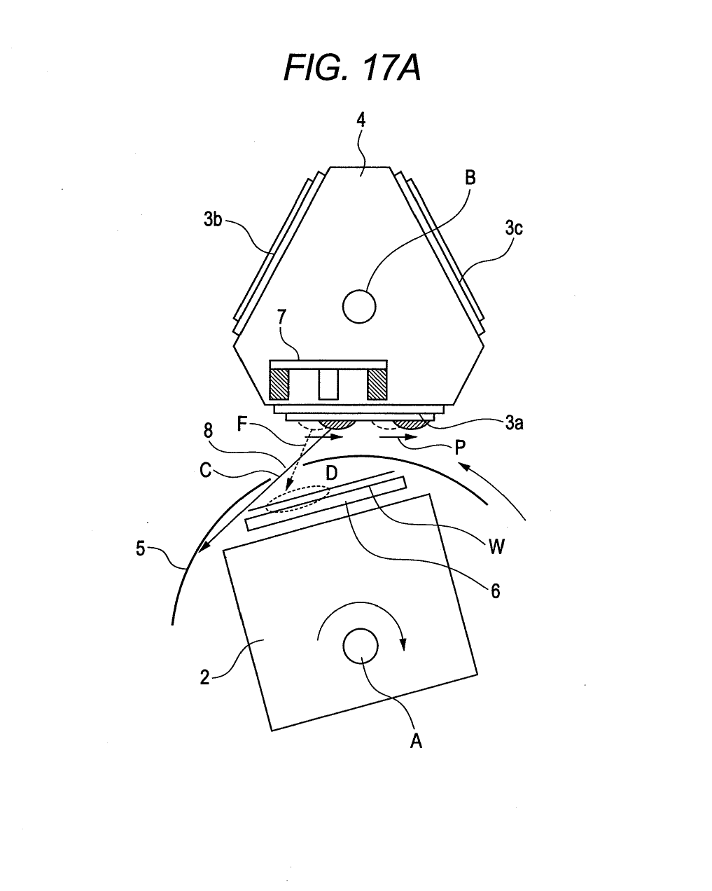

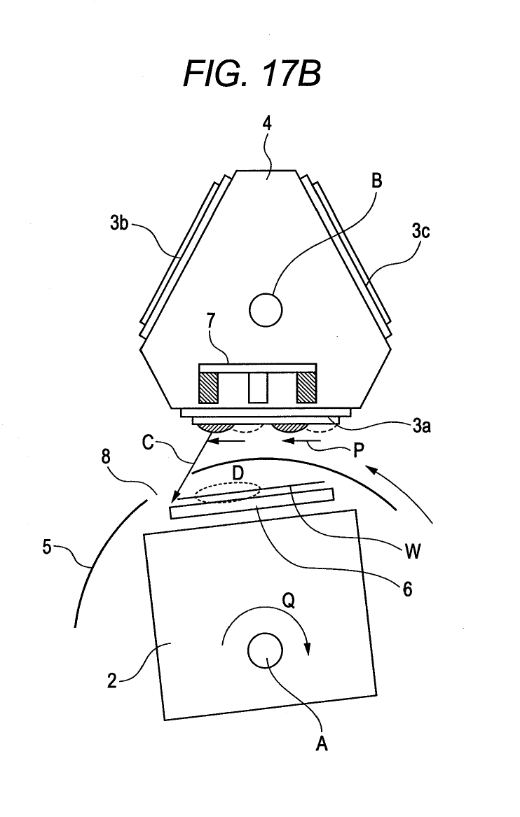

At this time, whether the cathode 4 is moving or standing still, since the cathode magnet 7 stands still with respect to the cathode 4, the sputter source 100 is not moved on the target 3, that is, the relative position of the sputter source 100 on the target 3 is not changed. Therefore, movement P of the sputter source 100 such as in FIGS. 17A and 17B can be suppressed. Thus, the sputter source 100 and the opening portion 8 can be brought into a desired positional relationship without controlling the movement of the shield plate 5 in a complicated manner, and the sputtered particles 101 can be made to enter the whole surface of the substrate W passing through the opposite side of the target 3 at a desired incident angle (or within a desired incident angle range).

Thus, if the film thickness for film formation is to be made smaller without lowering sputter power, for example, shift of the sputter source 100 with respect to the target 3 can be suppressed even if the moving speed of the stage 2 in the direction a can be increased, and thus, the sputtered particles 101 emitted from the sputter source 100 can be made to reach the whole surface of the substrate W at the desired incident angle uniformly through the opening portion 8 even without controlling the shield plate 5 in a complicated way. Thus, even in the case of film formation with a small film thickness, a film can be formed on the substrate W with uniform film thickness distribution.

In this description, the “incident angle” refers to an angle formed by a normal line of the surface to which the sputtered particles enter (the substrate surface of the substrate W or the like) and the incident direction of the incident sputtered particles.

In this embodiment, the range of the incident angle to the substrate W can be geometrically acquired. Therefore, if the rate of the sputtered particles entering the substrate W with an incident angle within a predetermined range is to be increased the most, the incident angle to the substrate corresponding to the predetermined angle can be geometrically acquired. Then, the control condition (the position of the target magnet 7, the position of the opening portion 8 and the like) may be obtained by simulation or the like so that the quantity of the sputtered particles incident to the substrate with the incident angle acquired as above becomes the largest.

When the film formation on the substrate W in the step 1 in FIG. 1A is finished, the process proceeds to the step 2 in FIG. 1A. The step 2 in FIG. 1A is a state in which the stage 2 having been conveyed stands by. The cathode magnet 7 is moved with respect to the target 3 during this period. The reason is to suppress concentration of erosion occurring on the target 3. That is, in the step 2, the controller 1000 controls the magnet driving mechanism in a state in which the stage 2 stands still, to move the cathode magnet 7 arranged at the first position in the direction α and to position it at the second position different from the first position.

In the step 2 in FIG. 1A, when the cathode magnet 7 is to be moved, power may be supplied to the cathode 4 or power supply may be stopped once. However, considering more effective use of the target, power supply to the cathode 4 is preferably stopped when cathode magnet 7 is moved.

When the movement of the cathode magnet 7 from the first position to the second position is finished, as in the step 3 in FIG. 1A, the stage 2 on which the substrate W is placed passes the opposite surface of the target 3 again (return path). If the power supply to the cathode 4 is stopped once in the step 2 in FIG. 1A, the controller 1000 resumes power supply to the cathode 4. In this step, since the cathode magnet 7 is arranged at the second position different from the first position (in the step 1 in FIG. 1A) inside the cathode 4, the sputter source 100 can be formed at a position different from that in the step 1 in FIG. 1A in a target 103. Therefore, in the step 3 in FIG. 1A, a region which is a non-erosion region in the step 1 in FIG. 1A can be made an erosion region, and the target 3 can be effectively used. Subsequently, the controller 1000 controls the stage driving mechanism to move the stage 2 in a direction β in parallel with the conveying direction Z and opposite to the direction α while the cathode magnet 7 is kept still with respect to the cathode 4. As a result, a series of film formation is finished. After that, the cathode magnet 7 is moved with respect to the target 3 again and returned to the position in the step 1 in FIG. 1A.

In this step, too, similarly to the step 1 in FIG. 1A, since the relative position of the sputter source 100 with respect to the target 3 is not changed, the sputtered particles 101 emitted from the sputter source 100 can uniformly reach the whole surface of the substrate W by the desired incident angle through the opening portion 8.

Another example of the operating method of the sputtering apparatus according to this embodiment will be described by using FIG. 1B. The step 1 in FIG. 1B illustrates, similarly to the step 1 in FIG. 1A, a state in which the stage 2 on which the substrate W is placed passes the opposite surface of the target 3 during the sputtering operation. The sputtering operation is being performed in a state in which the cathode magnet 7 stands still with respect to the target 3. Then, only the sputtered particles having passed through the slit 8 provided in the shield plate 5 contributes to film formation on the substrate W.

When the film formation on the substrate W in the step 1 in FIG. 1B is finished, the process proceeds to the step 2 in FIG. 1B. In the step 2 in FIG. 1B, the stage 2 is returned to the initial position, and the substrate W on which the film formation has been finished is recovered. That is, the controller 1000 stops power supply to the cathode 4 once, and controls the stage driving mechanism to move the stage 2 in the direction β, and to arrange the stage 2 at the initial position in the step 1 in FIG. 1B. At this time, when the processed substrate W is recovered, the new substrate W to be processed the next time can be placed on the stage 2. Subsequently, the new substrate W is arranged on the stage 2. The cathode magnet 7 is moved with respect to the target 3 during this period. The reason is to suppress concentration of erosion generated on the target 3 as described above. That is, the controller 1000 moves the cathode magnet 7 arranged at the first position in the direction α and positions it at the second position by controlling the magnet driving mechanism in a state in which the stage 2 stands still.

When the movement of the cathode magnet 7 is finished, the stage 2 on which the substrate W is placed as in the step 3 in FIG. 1B passes the opposite surface of the target 3 and performs the film forming operation. That is, the controller 1000 resumes power supply to the cathode 4 and generates the sputter source 100 in a region different from that in the step 1 in FIG. 1B. Subsequently, the controller 1000 moves the stage 2 in the direction α in parallel with the conveying direction Z in the state in which the cathode magnet 7 stands still with respect to the cathode 4 by controlling the stage driving mechanism.

As described above, in the mode in FIG. 1B, too, since the position of the cathode magnet 7 with respect to the target 3 is changed between the step 1 and the step 3 which are processes to convey the substrate and to form a film, a generation position of the sputter source 100 can be changed, and the effective use of the target 3 can be realized. Moreover, in the steps 1 and 3, since the cathode magnet 7 is kept still with respect to the target 3 (the cathode magnet 7 is fixed in the cathode 4), shifting of the sputter source 100 during film formation can be suppressed. Therefore, while the effective use of the target 3 is realized, the sputtered particles 101 can be caused to enter the whole surface of the substrate W at a desired incident angle.

As described above, in this embodiment, it is important to keep the cathode magnet 7 still with respect to the target 3 during a predetermined film formation step for the substrate W and to change the arranged position of the cathode magnet 7 with respect to the target 3 between two film formation steps (to change the arranged position of the cathode magnet 7 in the cathode 4). Therefore, the position of the cathode magnet 7 in the cathode 4 during the film formation step is not limited to the two types, that is, the above-described first position and the second position but may be a third position, a fourth position, . . . different from the first position and the second position. Alternatively, the position of the cathode magnet 7 in the cathode 4 during the conveying and film formation step may be changed for each conveying and film formation step, for example. Alternatively, a plurality of sessions of the conveying and film formation step are performed at the first position and when the plurality of sessions of the conveying and film formation step are finished, the conveying and film formation step may be performed at the second position.

Moreover, in FIGS. 1A and 1B, the mode in which the stage 2 is moved while the cathode 4 is fixed was described, but the stage 2 may be fixed while the cathode 4 is moved in the conveying direction Z during the film formation step or both the stage 2 and the cathode 4 may be moved as long as the arranged position of the cathode magnet 7 with respect to the target 3 can be changed between two film formation steps. At this time, the movement of the shield plate 5 may be controlled so that the sputtered particles with the predetermined incident angle enter the substrate W through the opening portion 8 from the sputter source 100. That is, in this embodiment, the controller 1000 controls the movement of at least one of the stage 2, the cathode 4, and the cathode magnet 7 so that the cathode magnet 7 is kept still with respect to the target 3 during the film formation step in which the film formation is performed while the position of the stage 2 and the position of the cathode 4 are relatively changed and the arranged position of the cathode magnet 7 with respect to the target 3 is changed between two film formation steps.

In FIGS. 1A and 1B, the sputtering apparatus which moves the stage 2 in parallel with the target 3 was described, but this embodiment can be applied to a sputtering apparatus in a mode of rotating the stage 2.

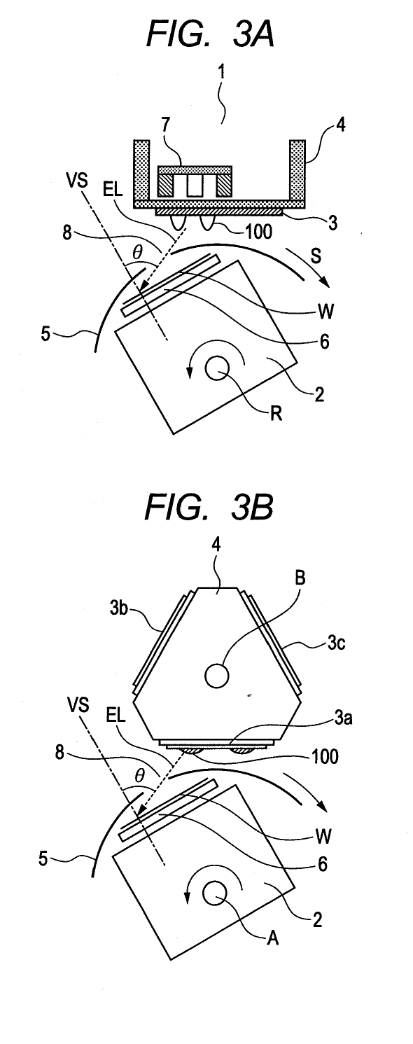

FIG. 3A is an outline side view illustrating an example of the sputtering apparatus which conveys the substrate W by rotating the stage 2 according to this embodiment. In FIG. 3A, the sputtering apparatus 1 includes the stage 2 on which the substrate W is placed, the cathode 4 supporting the target 3, and the shield plate 5 having the slit-shaped opening portion 8. In the mode in FIG. 3A, the stage 2 includes a rotating shaft R and is configured to rotate clockwise and counterclockwise by an arbitrary angle around the rotating shaft R. For example, the stage 2 can be rotated by using rotating means such as a motor, and the rotating means can be controlled by the controller 1000. Moreover, the cathode 4 is fixed in the sputtering apparatus 1. The rotating shaft R and the target 3 are supported by the cathode 4 so as to be in parallel.

Whether the stage 2 rotatable by an arbitrary angle around the rotating shaft R is standing still or rotating, the sputtered particles can be deposited on the substrate W by having ions in plasma collide against the surface of the target 3.

The substrate W to be subjected to the film formation processing by the target 3 is placed on the stage 2 rotatable by an arbitrary angle around the rotating shaft R. The stage 2 has a substrate placing base 6, and the substrate W can be provided on the substrate placing base 6. The substrate placing base 6 of the stage 2 is configured rotatable around a rotating shaft (not shown) perpendicular to the rotating shaft R and passing through the center of the substrate W and can rotate the substrate W around the rotating shaft. The substrate placing base 6 can be rotated by using rotating means such as a motor, for example, and this rotating means can be controlled by the controller 1000.

Moreover, the shield plate 5 having the slit-shaped opening portion 8 formed so that the sputtered particles can pass therethrough is provided between the target 3 and the stage 2, and the shield plate 5 has means for rotating around the rotating shaft R by an arbitrary angle and performs a function of fine adjustment of the film thickness distribution of the film to be deposited and of improving selectivity of the incident angle of the sputtered particles. The shield plate 5 can rotate around the rotating shaft R independently from the cathode 4 or the stage 2 by appropriately controlling rotating means for shield plate by the controller 1000.

FIG. 3B is also a diagram illustrating an example of the sputtering apparatus which conveys the substrate W by rotating the stage 2 according to this embodiment. In FIG. 3B, the sputtering apparatus 1 includes the stage 2 on which the substrate W is placed, the cathode 4 supporting the target 3, and the shield plate 5 having the slit-shaped opening portion 8. The stage 2 and the cathode 4 include a rotating shaft A and a rotating shaft B, respectively, and at least one of the stage 2 and the cathode 4 is configured to rotate clockwise or counterclockwise around the rotating shaft A and the rotating shaft B by an arbitrary angle. At least one of the stage 2 and the cathode 4 can be rotated by using rotating means such as a motor, for example, and the rotating means can be controlled by the controller 1000. The rotating shaft A and the rotating shaft B are arranged in parallel with each other, and the target 3 is supported by the cathode 4 so as to be in parallel with the rotating shaft B.

The target 3 supported by the cathode 4 rotatable around the rotating shaft B by an arbitrary angle can deposit the sputtered particles on the substrate W by having ions in plasma collide against the surface of the target 3 either while standing still or during rotation.

The substrate W subjected to the film formation processing by the target 3 is placed on the stage 2 rotatable around the rotating shaft A by an arbitrary angle. The stage 2 has the substrate placing base 6, and the substrate W can be provided on the substrate placing base 6. The substrate placing base 6 of the stage 2 is configured to be rotatable around a rotating shaft (not shown) perpendicular to the rotating shaft A and passing through the center of the substrate W and can rotate the substrate W around the rotating shaft. The substrate placing base 6 can be rotated by using rotating means such as a motor, for example, and this rotating means can be controlled by the controller 1000.

Moreover, the shield plate 5 having the slit-shaped opening portion 8 formed so that the sputtered particles can pass therethrough is provided between the target 3 and the stage 2. The shield plate 5 has means for rotating around the rotating shaft A by an arbitrary angle and performs a function of fine adjustment of the film thickness distribution of the film to be deposited and of improvement of selectivity of the incident angle of the sputtered particles. The shield plate 5 can rotate around the rotating shaft A independently from the cathode 4 or the stage 2 by controlling the rotating means for shield plate as appropriate by the controller 1000.

In FIG. 3B, the mode in which the shield plate 5 rotates around the rotating shaft A is illustrated, but the shield plate 5 may rotate around the rotating shaft B by providing the rotating means for shield plate on the cathode 4 side or the like.

The number of targets 3 supported by the cathode 4 is preferably plural. That is because of the following reason. A magnetic material used in a writing head has high saturated magnetic flux density such as a FeCo alloy in many cases, and the thickness of a target material that can be used in the sputter process is 4 to 5 mm at the largest. Thus, the number of processing that can form a film cannot be many. Then, by installing a plurality of the same target materials, continuous processing without a work of target replacement is realized. In the mode in FIG. 3B, a plurality of targets 3a, 3b, and 3c are present, and the targets 3a, 3b, and 3c can be used separately in accordance with the application as above and use applications as appropriate. The rotating shaft A and the rotating shaft B are arranged in parallel with each other, and the targets 3a, 3b, and 3c are supported by the cathode 4 so as to be in parallel with the rotating shaft B. The targets 3a, 3b, and 3c which are rotatable around the rotating shaft B have sputtered particles deposited on the substrate (W) by having ions in plasma collide against the surface of the targets. It is needless to say that the number of the targets may be one or may be plural.

In this description, the targets 3a to 3c might be collectively called the target 3.

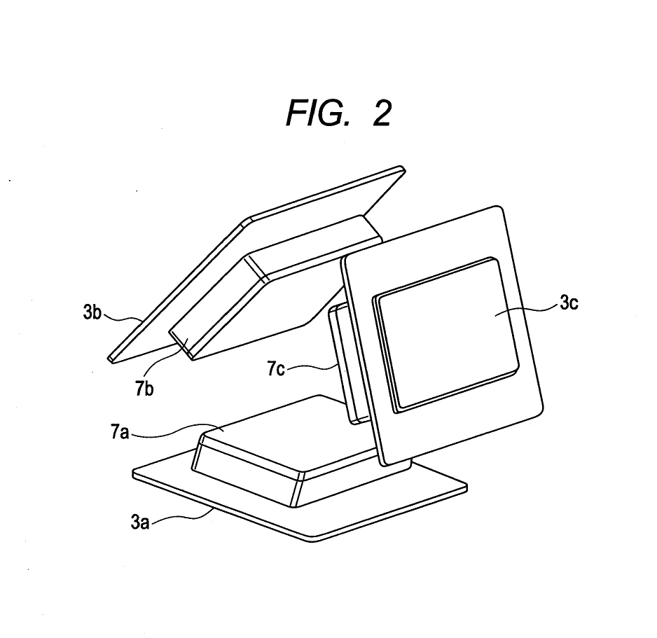

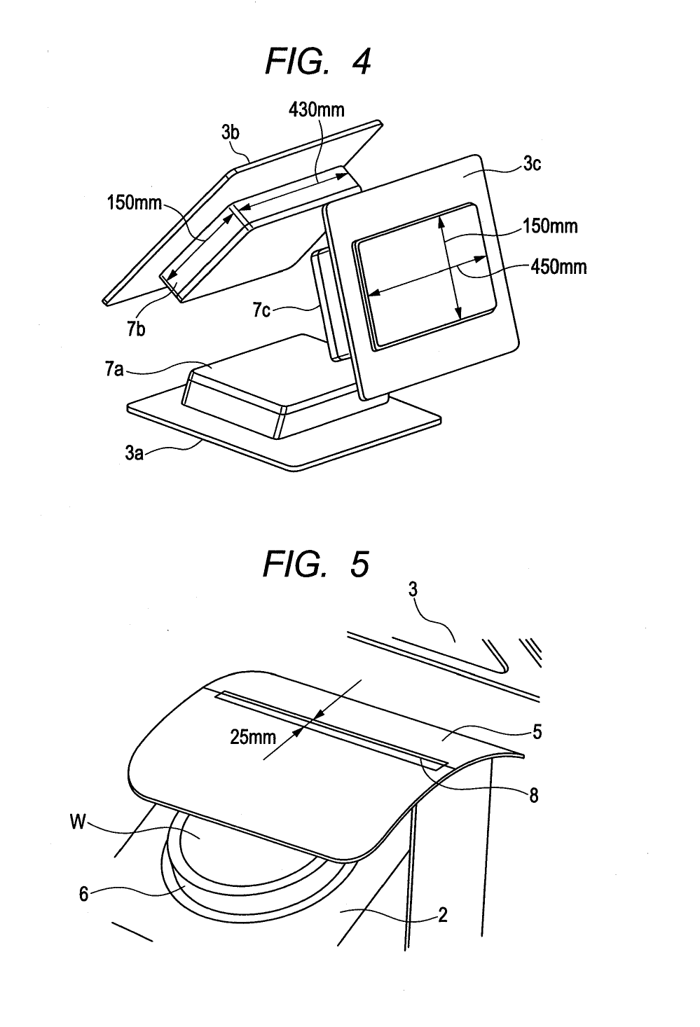

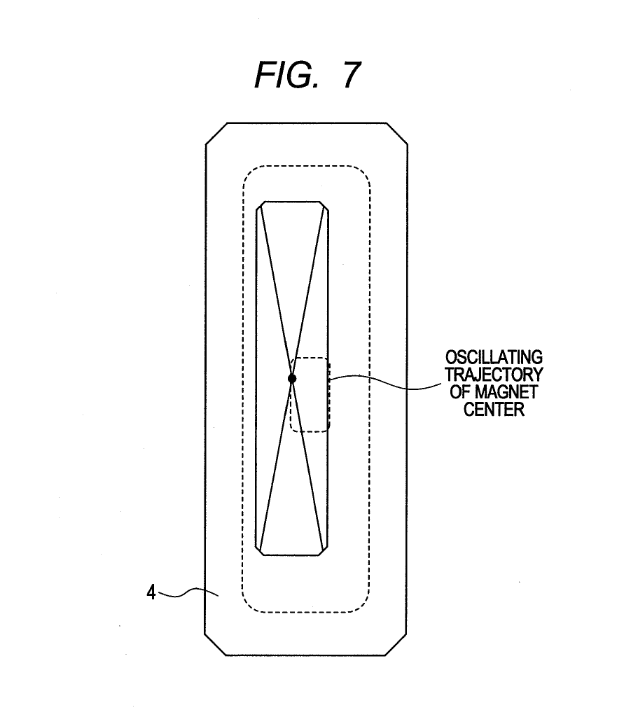

Moreover, the sputtering target 3a has a rectangular shape, and the length of the direction X perpendicular to the conveying direction (rotating direction S of the substrate) of the substrate W is longer than the direction Y parallel with that. The cathode magnets 7 which have magnetrons generated are placed in the number equal to that of the targets on the back sides of the discharge surfaces of the targets 3a, 3b, and 3c (FIG. 2). That is, as illustrated in FIGS. 2 and 4, cathode magnets 7a to 7c are provided in accordance with each of the targets 3a to 3c inside the cathode 4, and the cathode magnets 7a, 7b, and 7c are capable of reciprocating motion/oscillation in parallel with the targets 3a, 3b, and 3c, respectively. The reciprocating motion/oscillation of the cathode magnets 7a, 7b, and 7c draws a trajectory as in FIG. 7, for example.

As described above, in this embodiment, driving devices for rotation control (magnet driving mechanism, cathode driving mechanism, stage driving mechanism, and shield plate driving mechanism (none of them is shown)) are connected to the cathode magnet 7, the cathode 4, the stage 2, and the shield plate 5. Operations of these driving devices are executed by reading out control programs installed in a recording device provided in the controller 1000, not shown, for example, by a CPU as appropriate.

In this embodiment, arbitrary movement is made possible by the controller 1000 which controls the above-described plurality of driving devices linked with each other by using the control program. An example is that, by rotating the cathode 4 and the stage 2 in the same direction at the same speed, an operation in which the substrate W and the target 3 pass each other in the opposed state can be realized. Moreover, an operation in which the sputtered particles are made to adhere to the substrate W at a predetermined incident angle on a predetermined place of the substrate W by means of control of the shield plate 5 or fine adjustment of film formation time in an arbitrary region on the substrate W by changing these rotation speeds (driving speeds) can be also realized.

On the other hand, driving shafts are provided also in the cathode magnet 7 as the X axis in the longitudinal direction and the Y axis in the lateral direction of the target 3 illustrated in FIG. 3B, and the oscillating motion of the cathode magnet 7 is executed by having the CPU read out the control program installed in the recording device provided in the controller 1000, similarly not shown. As a result, the cathode magnets 7a to 7c can draw an arbitrary trajectory on the back faces of the targets 3a, 3b, and 3c. This trajectory is possible both in a continuous operation or a repeated operation of “move” and “stand still”. It is needless to say that the moving (reciprocating) speed of the magnet 7 can be increased by increasing the driving speed of the cathode magnet 7 and vice versa. By stopping the control of the magnet driving mechanism which is a driving part, the magnet 7 can be also kept still at an arbitrary place.

The control systems of the cathode 4, the stage 2, the shield plate 5, and the cathode magnet 7 can be all operated by linking the driving systems with each other by the control program.

FIGS. 4 and 5 are explanatory diagrams illustrating a dimension relationship among the target 3, the cathode magnet 7, and the slit 8. The target 3, the cathode magnet 7, and the slit 8 width provided in the shield plate 5 illustrated in the above-described FIG. 3B were fabricated with the sizes illustrated below.

| | |
|---|---|
| Target 3 | X-direction length: 450 mm |
| | Y-direction length: 150 mm |
| Cathode magnet 7 | X-direction length: 430 mm |
| | Y-direction length: 120 mm |
| slit 8 | 25 mm width |

### Comparative Example 1

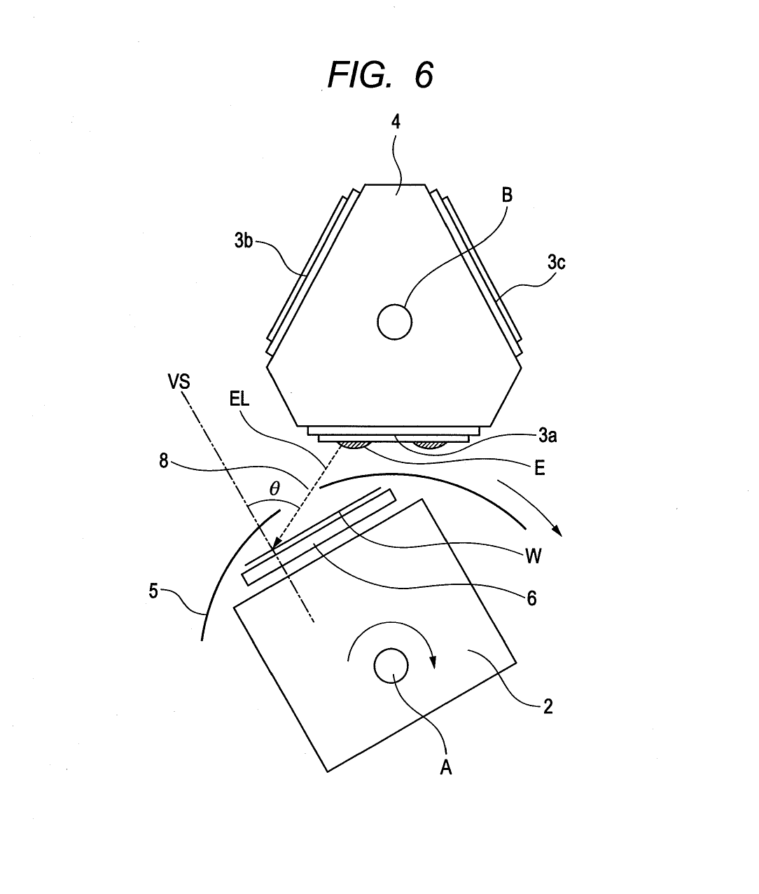

In order to make clear the effects of the present invention, a result by the method using the prior-art method, that is, an oscillating motion is illustrated below. As illustrated in FIG. 6, a method in which the target 3 is fixed, the stage 4 is rotated, and the shield plate 5 is rotated around the rotating shaft B so that a film is formed while passing in front of the target 3 is exemplified. When the stage 2 rotates and passes in front of the target 3, rotation is controlled so that an angle θ formed by an extension EL to the substrate W connecting the slit 8 end provided in the shield plate 5 and the sputter source (100) on the target 3, that is, a region E where plasma is generated and a normal vector VS on the substrate W surface at the intersection with the substrate W is kept constant at a set value (FIG. 6). Here, the magnet makes a reciprocating (oscillating) motion substantially in an ellipse shape (FIG. 7) with 1 Hz as before.

In film formation, in order to obtain

θ=30 degrees,

automatic adjustment is made so that a speed of each part is as follows:

| | |
|---|---|
| cathode 4 | 0 degrees/second (stand-still) |
| stage 2 | 5 degrees/second |
| shield plate 5 | θ = 30 |

Reciprocating (oscillating) motion of the magnet 7 1 Hz, and discharge power was set at 1000 watt.

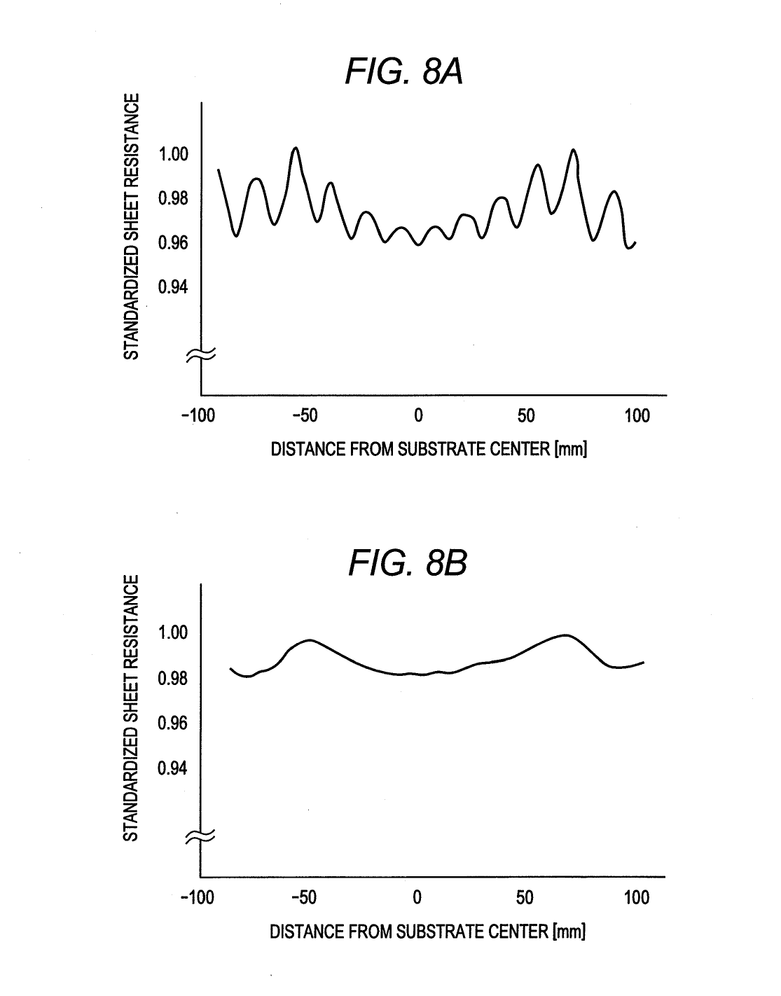

As a result, the surface resistance distribution is as illustrated in FIG. 8A, and wavy distribution occurred in the substrate traveling direction. The size of the surface resistance (hereinafter referred to as “sheet resistance distribution”) distribution per unit area in this direction was 13% in RANGE/MEAN. The “RANGE/MEAN=(sheet resistance maximum value−sheet resistance minimum value)/sheet resistance average value”. This wavy distribution occurs since the rotation speed of the stage 2 is too fast.

This will be described by using FIGS. 17A and 17B. In the prior-art method, a film is formed by means of oscillation of the cathode magnet 7 with the rotation of the stage 2. The sputtered particles generated from the sputter source pass through the slit 8 and reach the film-formation target substrate W, but if the position of the sputter source has a relationship as illustrated in FIG. 17A due to the oscillation, the sputtered particles might pass a trajectory C not reaching the substrate W. When the stage 2 continues to rotate from FIG. 17A to FIG. 17B as it is, a region D to which the film does not adhere occurs, and the film thickness distribution is deteriorated.

That is, since the cathode magnet 7 is also moved during the film formation, the sputter source is also moved with the movement, and the trajectory of the sputtered particles incident to the substrate W might deviate from an original particle trajectory F having a desired incident angle. In this case, since the position of the sputter source is deviated from the position which becomes the generation source of the original particle trajectory F, the sputtered particles incident to the substrate W from the deviated sputter source might be blocked by the shield plate 5. If there is a block as above, the sputtered particles, which should have been caused to enter the arbitrary region D which the sputtered particles should have reached do not reach the region D, and thus, sputtered particles with an unintended incident angle might enter the arbitrary region or no sputtered particles might enter. As a result, sheet resistance is varied in the plane of the substrate W.

### Comparative Example 2

In order to further make clear the effects of the present invention, an experiment was conducted under the following conditions by the prior-art method:

In order to obtain

θ=60 degrees,

automatic adjustment is made so that a speed of each part is as follows:

| | |
|---|---|
| cathode | 0 degrees/second (stand-still) |
| stage | 1.3 degrees/second |
| shield plate | θ = 60 |

Reciprocating (oscillating) motion of the magnet 7 1 Hz, and discharge power was set at 1000 watt.

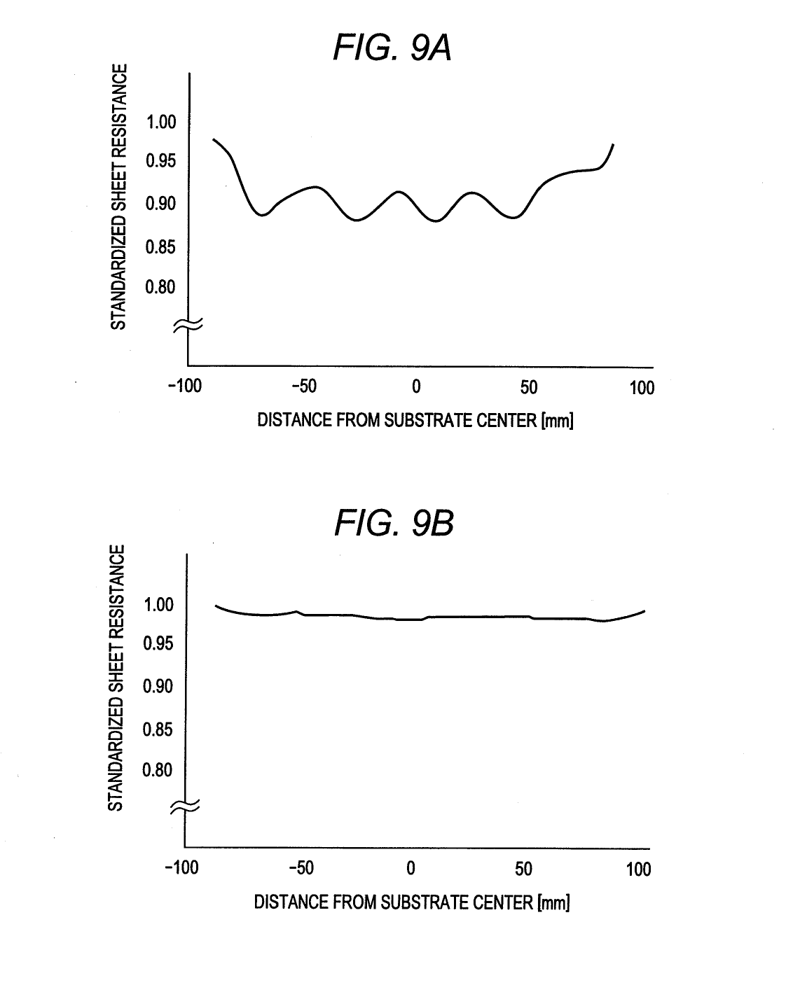

As a result, the surface resistance distribution is as illustrated in FIG. 9A, and wavy distribution occurred in the substrate traveling direction. The distribution was 20% by the similar calculating method. The reason why such a phenomenon occurs is as already described.

### First Example

A first example of the invention of the present application will be described. The first example is characterized by having a first step in which the cathode magnet 7 is fixed at a first position inside the cathode 4, and a film is formed on the substrate W on the substrate support surface of the stage 2, a second step in which after the film formation on the substrate W is finished, the cathode magnet 7 is moved to a second position inside the cathode 4 different from the first position and fixed, and a third step in which the film is formed on the substrate W on the substrate support surface of the stage 2 by using the cathode magnet 7 fixed at the second position.

A result by this example will be illustrated below. As in FIG. 6, a method in which the target 3 is fixed, the stage 2 is rotated, and the shield plate 5 is rotated around the rotating shaft B and a film is formed so that a film is formed while passing in front of the target 3 is exemplified. When the stage rotates and passes in front of the target 3, rotation is controlled so that the angle θ formed by the extension EL to the substrate connecting the slit 8 end provided in the shield plate 5 and the sputter source on the target 3, that is, the region E where plasma is generated and the normal vector VS on the substrate surface at the intersection with the substrate is kept constant at a set value (FIG. 6). Here, the cathode magnet 7 is fixed to the center position (first position) of the target 3.

In the first film formation, in order to obtain

θ=30 degrees,

automatic adjustment is made so that a speed of each part is as follows:

| | |
|---|---|
| cathode 4 | 0 degrees/second (stand-still) |
| stage 2 | 5 degrees/second |
| shield plate 5 | θ = 30 |

The discharge power was set at 1000 watt.

As a result, the surface resistance distribution in this example is as illustrated in FIG. 8B, and the wavy distribution occurring in the substrate traveling direction in FIG. 8A was reduced. The size of the sheet resistance distribution in this direction was 1.2% in RANGE/MEAN. The “RANGE/MEAN=(sheet resistance maximum value−sheet resistance minimum value)/sheet resistance average value”.

In the first example, after the first film formation was finished, the cathode magnet 7 is moved from the center to the right-side position (second position) of the target 3, and the cathode magnet 7 was fixed to the target 3. After that, second film formation was performed.

In the second film formation, in order to obtain

θ=30 degrees,

automatic adjustment is made so that a speed of each part is as follows:

| | |
|---|---|
| cathode 4 | 0 degrees/second (stand-still) |
| stage 2 | 5 degrees/second |
| shield plate 5 | θ = 30 |

The discharge power was set at 1000 watt.

As described above, according to the first example, since the second film formation was performed by fixing the cathode magnet 7 at the second position different from the first position, the effect that film thickness distribution can be improved without deteriorating the target use efficiency can be exerted even though the magnet was fixed during the film formation.

### Second Example

In order to demonstrate that the effect of the present invention is still effective even if the sputter incident angle is changed, an experiment was conducted also for the following condition as a second example:

In order to obtain

θ=60 degrees,

automatic adjustment is made so that a speed of each part is as follows:

| | |
|---|---|
| cathode 4 | 0 degrees/second (stand-still) |
| stage 2 | 1.3 degrees/second |
| shield plate 5 | θ = 60 |

The discharge power was set at 1000 watt.

As a result, the surface resistance distribution in this example is as in FIG. 9B, the distribution in the substrate traveling direction was 2%, and it was made clear that the present invention is still effective even though the sputter incident angle is changed.

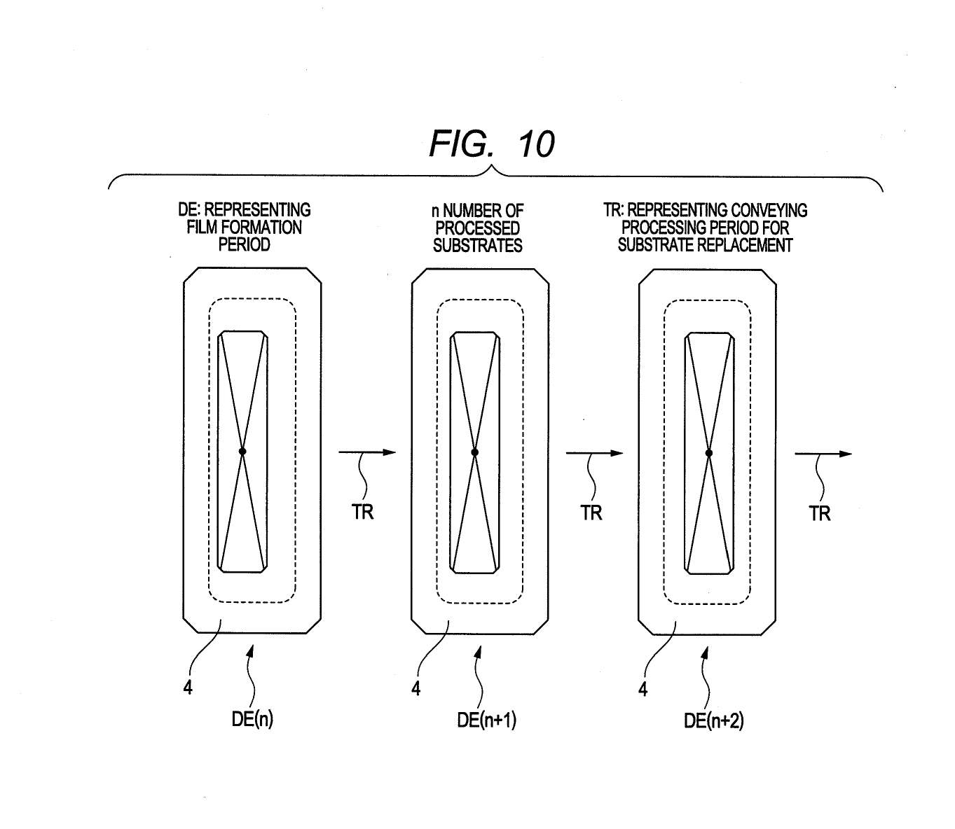

After the sputter film formation is finished, the fixed position of the cathode magnet 7 may be shifted to the second position different from the first position during the conveying processing of the substrate W so as to apply the sputter film formation processing to the subsequent substrate W (FIG. 10). As a result, erosion can occur on the whole surface of the target, and occurrence of a non-erosion region on the target can be prevented or reduced. The direction to shift the fixed position of the cathode magnet 7 is preferably a direction in parallel with the substrate W moving direction.

The moving distance of the cathode magnet 7 during the substrate conveying processing should be optimized in accordance with the discharge time and the sputter film thickness, and it is preferable the whole surface of the target is covered by 5 to 10 pieces of the substrates. With the substrates more than that, many recoil sputter atoms adhere onto the target before the sputter source comes. On the other hand, with the substrates fewer than that, adhesion of the recoil sputter atoms can be prevented, but erosion can easily concentrate, and target use efficiency is lowered.

On the other hand, if the discharge time is extremely short such as several seconds, the number of substrates to be processed until the cathode magnet 7 is moved to an arbitrary position may be plural. In the case of AlTiC (aluminum titanium carbide), for example, a load lock can contain 10 to 16 substrates therein, and erosion can be obtained on the whole surface of the target without occurrence of a non-erosion region on the target even if the fixed position of the cathode magnet 7 is shifted after the film formation processing is finished by this containing unit. Since the operation of the cathode magnet 7 becomes less, it also has an advantage that a difference in film thickness and film thickness distribution between the substrates can hardly occur.

Since the shield plate 5 can freely rotate, even if the fixed position of the cathode magnet 7 in a position within the target surface is changed, the relationship among the substrate W—slit 8—(changed position of) sputter source 100 can be adjusted all the time. That is, the angle of the sputtered particles 101 incident onto the substrate can be modified regardless of the fixed position of the cathode magnet 7 (sputter source 100), and the film quality is not changed by the processed substrate.

### Second Embodiment

Subsequently, a second embodiment of the invention of the present application will be described. In the second embodiment, in the sputtering apparatus illustrated in FIG. 3B, start of a first motion of the cathode magnet 7 moving in a direction Z′ in parallel with the conveying direction Z of the substrate W when the processed surface of the substrate W becomes substantially parallel with the surface of the target 3 during first film formation is synchronized with start of first rotary motion (start of a rotary motion so as to realize the conveying direction Z) of at least one of the shield plate 5 and the stage 2, and also, end of the first motion (end of the movement in the direction in parallel with the direction Z′ of the substrate W) of the cathode magnet 7 is synchronized with the end of the first rotary motion (end of the rotary motion so as to realize the conveying direction Z) of at least one of the shield plate 5 and the stage 2 while a film is formed on the substrate W on the substrate support surface of the stage 2.

Moreover, in the second embodiment, it may be so configured that in second film formation subsequent to the first film formation, start of a second motion in a direction opposite to the moving direction in the first film formation of the cathode magnet 7 is synchronized with start of second rotary motion in a rotating direction opposite to the rotating direction in the first film formation of at least one of the shield plate 5 and the stage 2, and also, the end of the second motion of the cathode magnet 7 and the end of the second rotary motion of at least one of the shield plate 5 and the stage 2 while a film is formed on the substrate W on the substrate support surface of the stage 2.

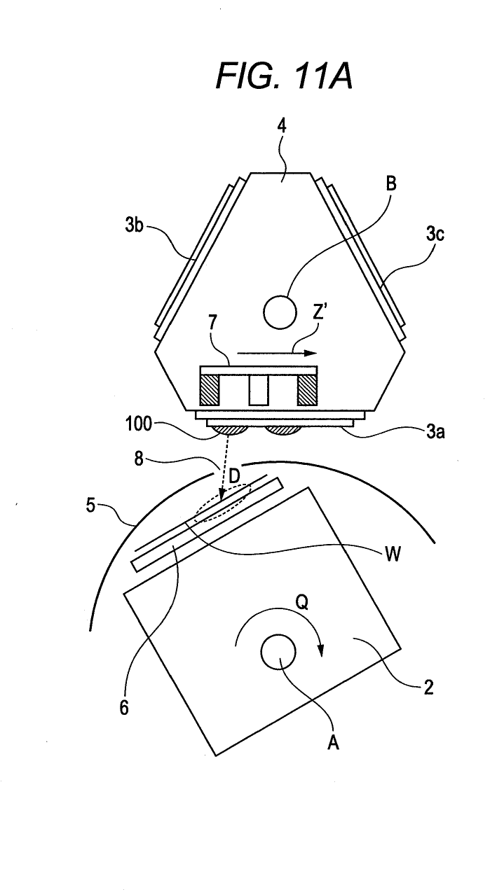

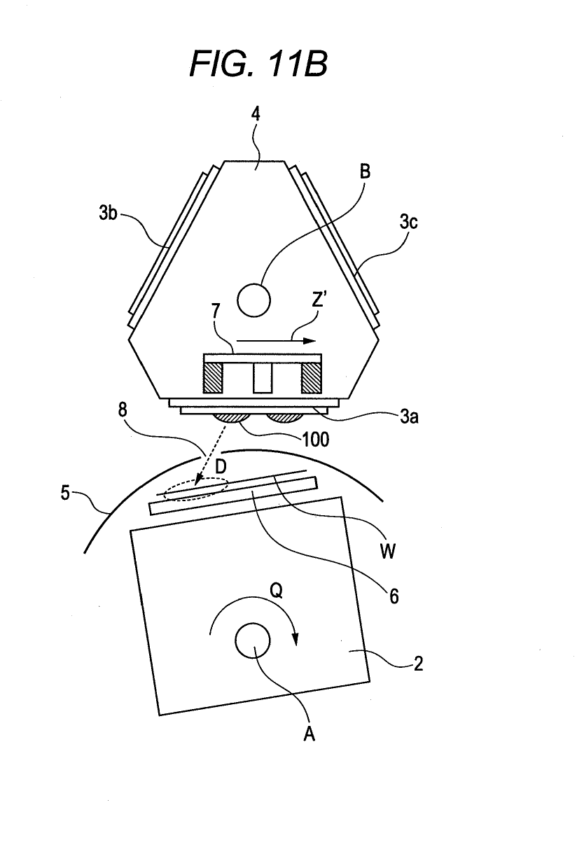

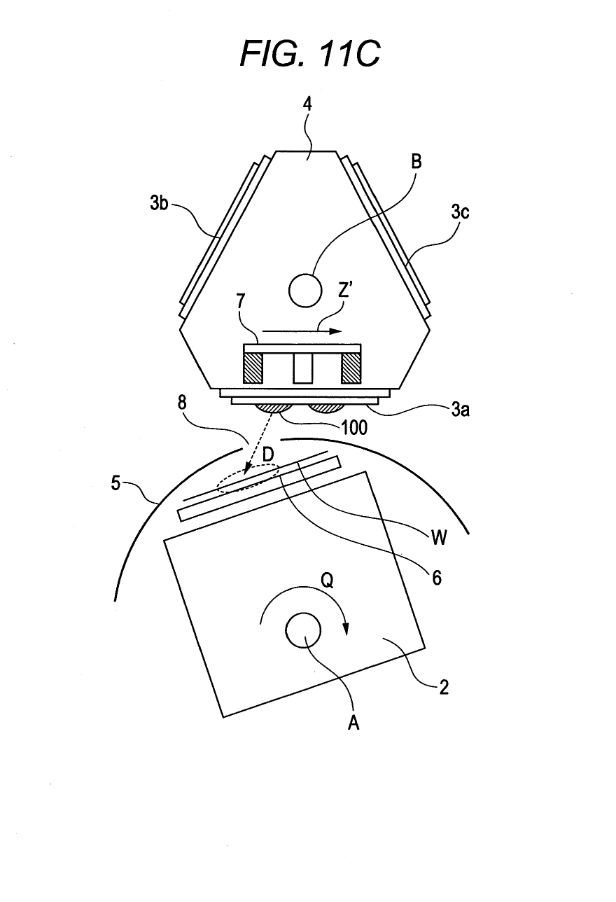

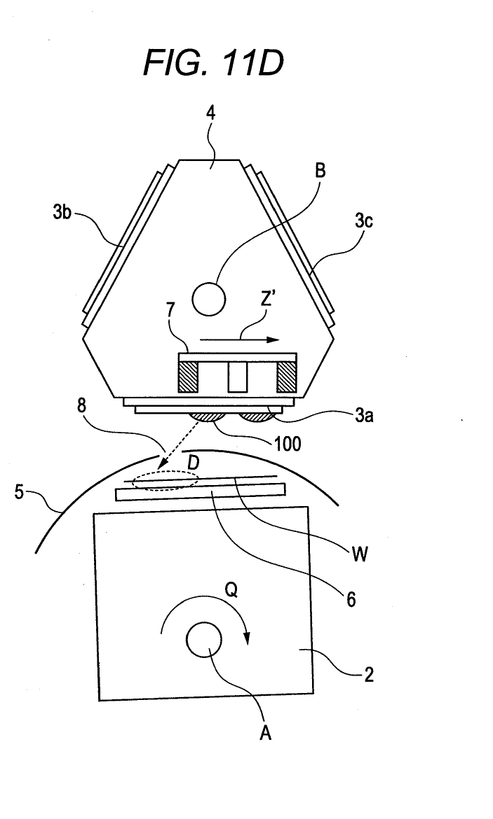

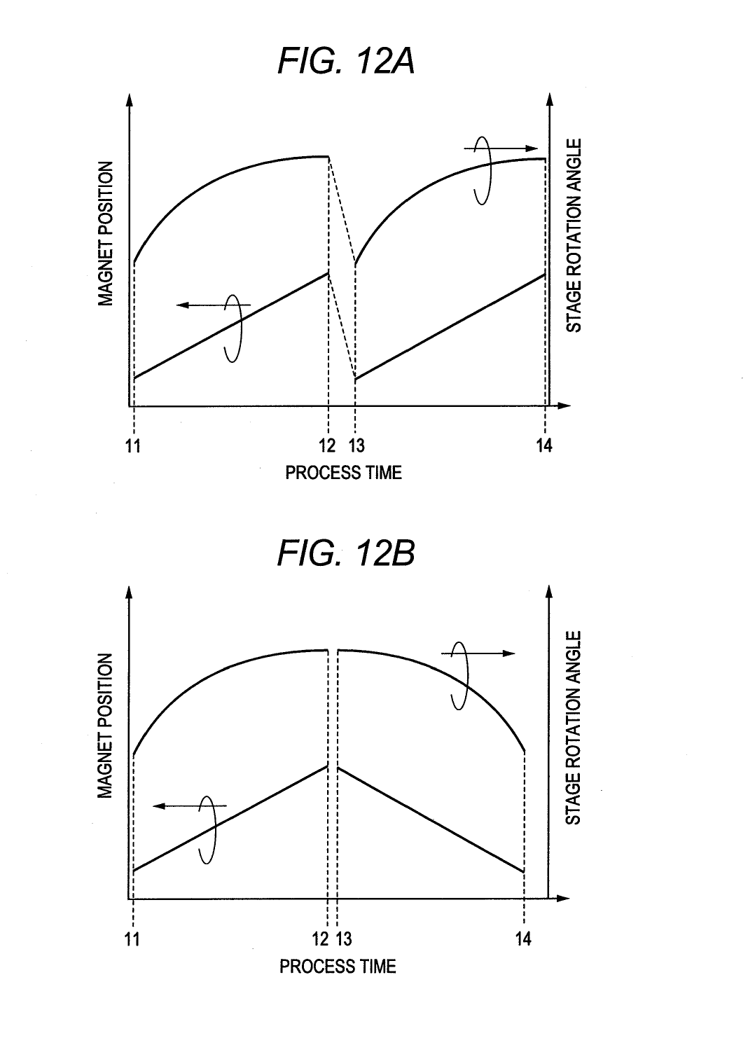

According to the second embodiment of the invention of the present application, moreover, if discharge power is to be increased in order to raise a film formation rate (4000 W or more in the above dimension, for example), re-adhesion of the film on the target 3 by recoil of the sputtered particles from the substrate W can be suppressed by moving the cathode magnet 7 during the sputter film formation on the substrate W. An example of the motion method of the cathode magnet 7 at this time is illustrated in FIGS. 11A, 11B, 11C, and 11D. Moreover, reference numerals 11, 12, 13, and 14 described in FIGS. 12A, 12B refer to a motion start position 11 during the first film formation, a motion end position 12 during the first film formation, a motion start position 13 during the second film formation, and the motion end position 14 during the second film formation, of the cathode magnet 7 and the stage 2, respectively.

In the mode in FIG. 12A, the moving direction of the cathode magnet 7 and the rotating direction of the stage 2 are the same in the first film formation and the second film formation. In this mode, the cathode magnet 7 can move in the first moving direction Z′, the stage 2 can rotate in a first rotating direction Q, and the first moving direction and the first rotating direction are set so that the conveying direction (moving direction of the stage 2 in this case: tangent direction in the rotating direction) matches the first moving direction Z′ when the stage 2 rotates in the first rotating direction Q and the substrate placing surface of the stage 2 becomes substantially parallel with the surface of the target 3.

In the mode in FIG. 12A, the controller 1000 controls the magnet moving mechanism to position the cathode magnet 7 at a first arranged position (corresponding to the motion start position 11 in the first film formation) in the cathode 4 and also controls the stage driving mechanism to position the stage 2 at the first rotation position (corresponding to the motion start position 11 in the first film formation). At this time, as illustrated in FIG. 11A, the stage 2, the cathode magnet 7, and the shield 5 are positioned so that the sputtered particles incident to the arbitrary region D on the substrate W through the opening portion 8 from the sputter source 100 have an incident angle within a predetermined range while the stage 2, the cathode magnet 7, and the shield plate 5 are stopped.

Subsequently, the controller 1000 controls the magnet driving mechanism, the stage driving mechanism, and the shield plate driving mechanism to move the cathode magnet 7 positioned at the first arranged position in the first moving direction Z′, rotates the stage 2 positioned at the first rotation position in synchronization with the movement of the cathode magnet 7 in the first rotating direction Q, and rotates the shield plate 5. If the stage 2 is rotated in the first rotating direction Q as above, the position of the substrate placing surface of the stage 2 has a circular trajectory but changes in the first moving directions Z′, for example, and thus, the stage 2 can be considered to be displaced so as to generate displacement in the first moving direction Z′.

As described above, movements (displacements) of the cathode magnet 7, the stage 2, and the shield plate 5 in the first film formation are started.

Subsequently, the controller 1000 performs the first film formation by controlling the movements (displacements) of the cathode magnet 7, the stage 2, and the shield plate 5 started in synchronization as illustrated in FIGS. 11B to 11C. Then, when the cathode magnet 7 is positioned at the second arranged position (corresponding to the motion end position 12 in the first film formation) in the cathode and the stage 2 is positioned at the second rotation position (corresponding to the motion end position 12 in the first film formation), the controller 1000 controls the magnet driving mechanism, the stage driving mechanism, and the shield plate driving mechanism 5 to stop the rotation of the stage 2 and the rotation of the shield plate 5 in synchronization with the stop of the movement of the cathode magnet 7 in the first film formation. As described above, the motions (displacements) of the cathode magnet 7, the stage 2, and the shield plate 5 in the first film formation are stopped, and the predetermined film formation is finished.

In this embodiment, since the cathode magnet 7 is moved with respect to the target 3 during the film formation, the sputter source 100 is also moved, but displacement (rotation) of at least one of the stage 2 and the shield plate 5 is started in synchronization with start of the displacement (movement) of the cathode magnet 7. Therefore, the appropriate positional relationship among the opening portion 8, the substrate W and the sputter source 100 can be maintained in accordance with the movement of the sputter source 100. Therefore, even if the cathode magnet 7 is moved during the film formation for effective use of the target 3, the sputtered particles with the desired incident angle can be caused to enter the whole surface of the substrate W.

When the first film formation is finished, the controller 1000 controls the cathode driving mechanism to position the cathode magnet 7 at the first arranged position (corresponding to the motion start position 13 in the second film formation) in the cathode 4 and controls the stage driving mechanism to position the stage 2 at the first rotation position (corresponding to the motion start position 13 in the second film formation). Subsequently, when the cathode magnet 7 is positioned at the second arranged position (corresponding to the motion end position 14 in the second film formation) and the stage 2 is positioned at the second rotation position (corresponding to the motion end position 14 in the second film formation), the controller 1000 controls the magnet driving mechanism and the stage driving mechanism to stop the rotation of the stage 2 in synchronization with the stop of the movement of the cathode magnet 7 in the second film formation similarly to the above.

On the other hand, in the mode in FIG. 12B, the moving direction of the cathode magnet 7 and the rotating direction of the stage 2 are opposite between the first film formation and the second film formation. Therefore, the first film formation corresponds to an outward path and the second film formation corresponds to a return path.

In the method of this second embodiment, the moving cycle of the magnet 7 (time required to move from the first arrangement position to the second arrangement position) is preferably matched with the cycle of the stage 2 rotating around the shaft A (time required to rotate from the first rotation position to the second rotation position). Since the magnet 7 is still moving during the sputtering, sputtering is performed by the sputter source 100 moving even if the recoil sputtered particles from the substrate W adhere to the target 3, and re-adhesion of the film is suppressed.

If the movement cycle of the cathode magnet 7 is set shorter than the cycle of the stage 2 rotating around the shaft A, turning is generated during the motion of the cathode magnet 7 in the middle of the film formation, and film formation with uniform film thickness as in FIGS. 17A and 17B might become impossible. On the other hand, if the movement cycle of the cathode magnet 7 is made slower than the cycle of the stage 2 rotating around the shaft A, film thickness uniformity can be maintained but a moving range of the cathode magnet 7 does not cover the whole surface of the target 3 during the film formation, and a non-erosion region might occur.

In the method of this second embodiment, too, the shield plate 5 can be freely rotated, and even if the fixed position of the cathode magnet 7 is changed in the plane of the target 3, the relationship among the substrate W—slit 8—(changed position of) sputter source 100 can be adjusted all the time. That is, the angle of the sputtered particles incident onto the substrate W can be modified regardless of the fixed position of the magnet (sputter source), and the film quality is not changed by the processed substrate.

Also, in the method of the second embodiment, the movement cycle of the cathode magnet 7 may be matched with the cycle of the shield plate 5 rotating around the shaft A. In this case, since the stage 2 can freely rotate, even if the fixed position of the cathode magnet 7 is changed in the plane of the target 3, the relationship among the substrate W—slit 8—sputter source 100 (whose position is changed) can be adjusted all the time. That is, the angle of the sputtered particles incident onto the substrate W can be modified regardless of the fixed position of the magnet (sputter source), and the film quality is not changed by the processed substrate.

In the above description, the mode in which the stage 2 is rotated around the rotating shaft A as illustrated in FIG. 3B has been described, but it is needless to say that this embodiment can be applied to the mode in which the stage 2 is moved in parallel with the target 3 as illustrated in FIGS. 1A and 1B.

### Third Embodiment

In this embodiment, the controller 1000 described in the first embodiment and the second embodiment will be described. The controller 1000 can function as a control mechanism which controls at least one of the movements of the cathode 4, the cathode magnet 7, and the stage 2 so that, as in the first embodiment, a film is formed on the substrate W by conveying the substrate W while the cathode magnet 7 is stopped with respect to the target 3 in the first film formation step in which the film is formed on the substrate W by relatively moving the cathode 4 and the stage 2, and when the first film formation step is finished, the cathode magnet 7 is moved to a position different from that in the first film formation step and the second film formation step is executed while the cathode magnet 7 is kept still with respect to the target 3 at the different position.

Moreover, the controller 1000 can also function as a control mechanism which synchronizes start of displacement of the cathode magnet 7 in film formation with start of displacement of at least one of the shield plate 5 and the stage 2 and also synchronizes end of the displacement of the cathode magnet 7 with end of the displacement of at least one of the shield plate 5 and the stage 2.

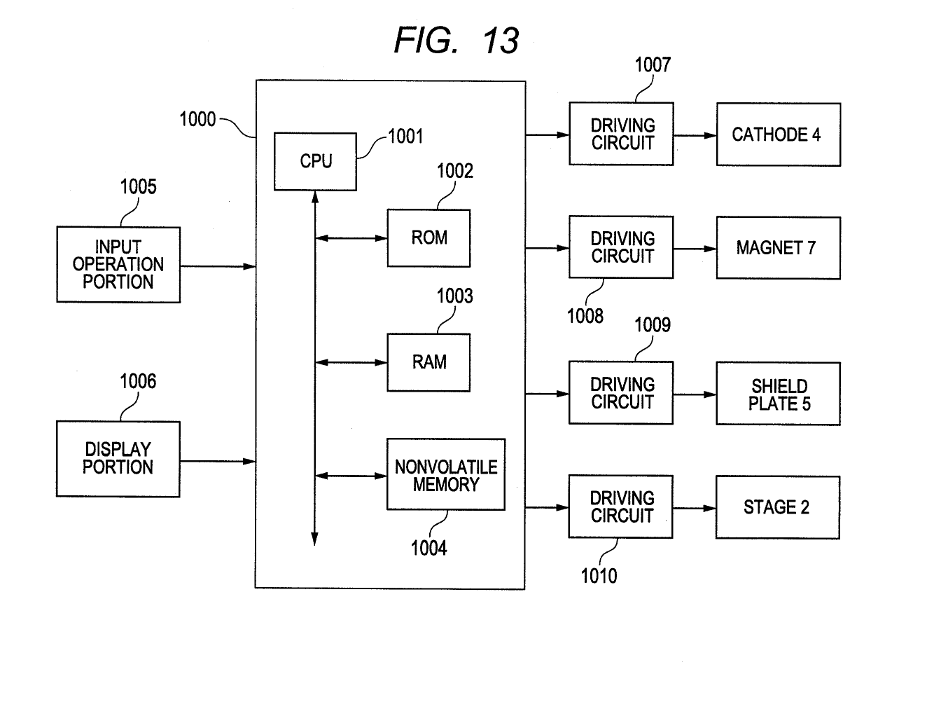

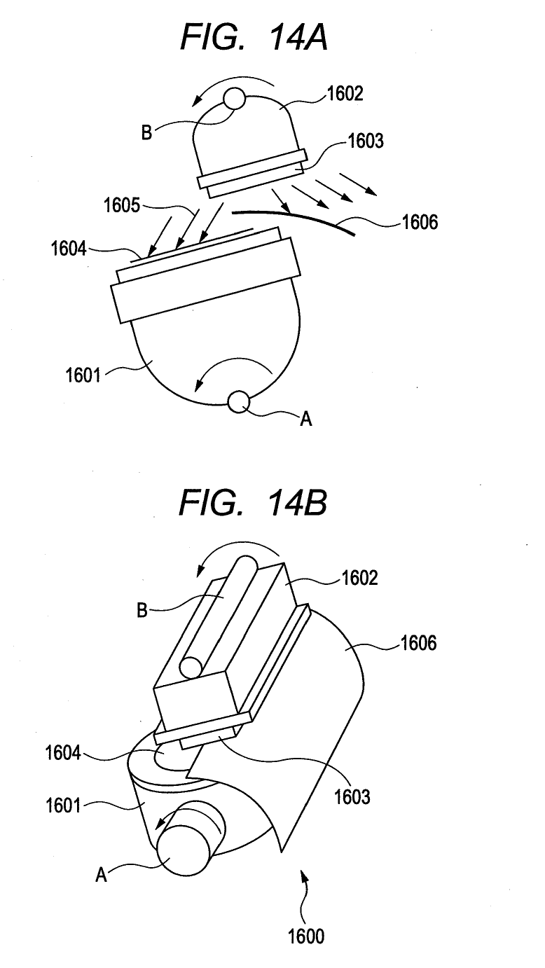

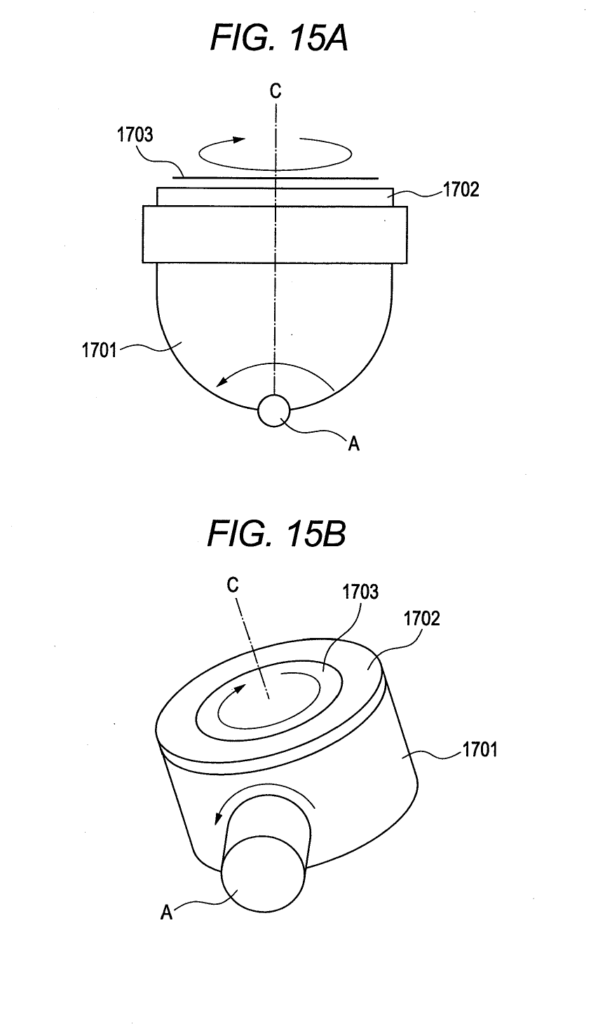

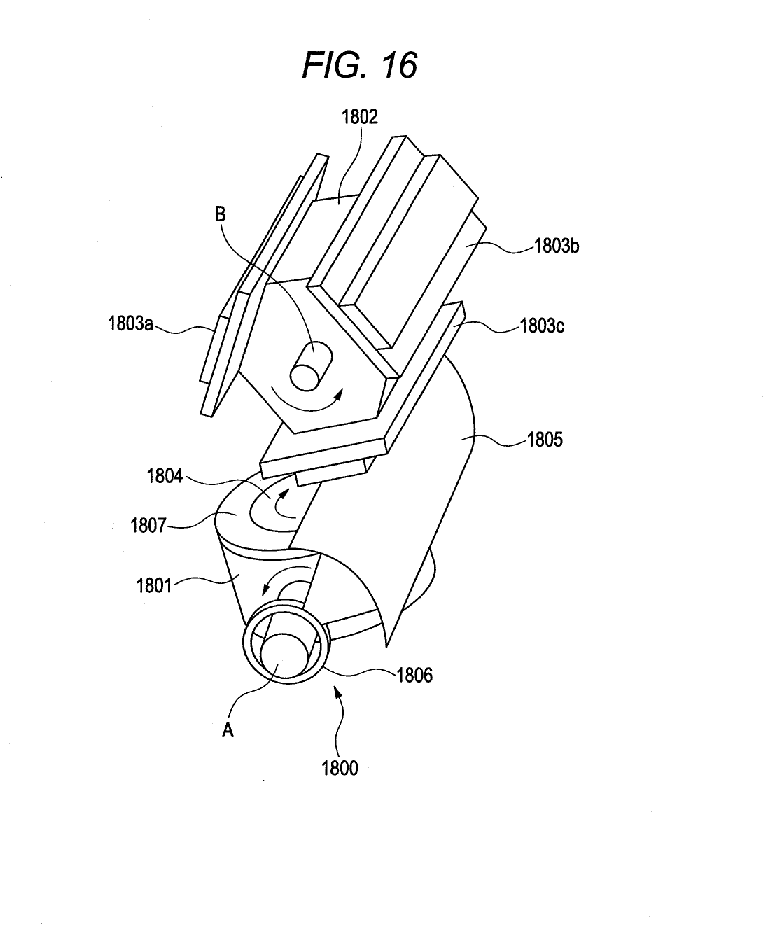

FIG. 13 is a block diagram illustrating an outline configuration of a control mechanism in a sputtering apparatus in a third embodiment. In FIG. 13, reference numeral 1000 denotes a control mechanism (controller) as control means which controls the entire sputtering apparatus. This controller 1000 has a CPU 1001 which executes processing operations including various calculations, controls, determinations and the like and a ROM 1002 which stores various control programs executed by this CPU 1001. Moreover, the control portion 1000 has a RAM 1003 which temporarily stores data during a processing operation of the CPU 1001, input data and the like, a nonvolatile memory 1004 such as a flash memory, a SRAM and the like.

Moreover, to the control mechanism 1000, an input operation portion 1005 including a keyboard for inputting predetermined instructions or data or various switches and the like and a display portion 1006 which makes various displays including input/setting states of the sputtering apparatus and the like are connected. Moreover, to the control mechanism 1000, the cathode 2, the cathode magnet 7, the shield plate, and the stage 2 are connected through driving circuits 1007, 1008, 1009, and 1010, respectively.

On executing the operation of the first embodiment, in accordance with an instruction from the CPU 1001, the sputtering apparatus 1 conveys the substrate W and performs film formation on the substrate W while the cathode magnet 7 is stopped with respect to the target 3 in the first film formation step, and when the first film formation step is finished, the sputtering apparatus 1 performs the second film formation step in which the cathode magnet 7 is moved to a position different from that in the first film formation step while the cathode magnet 7 stands still with respect to the target 3 at the different position.

Moreover, when the operation of the second embodiment is to be executed, in accordance with an instruction from the CPU 1001, start of the displacement of the cathode magnet 7 in film formation is synchronized with start of the displacement of at least one of the shield plate 5 and the stage 2 and also, end of the displacement of the cathode magnet 7 is synchronized with end of the displacement of at least one of the shield plate 5 and the stage 2.

1-18. (canceled)

19. A film forming method using an apparatus including a cathode having a sputtering target support surface for holding a sputtering target, a stage having a substrate support surface for holding a substrate, and a magnet disposed in the cathode, the method comprising:
a first step of generating a plasma by applying a power to the cathode and depositing a film on the substrate, while the magnet is kept still with respect to the sputtering target by being fixed at a first position in the cathode and the stage is moved in a first direction;
a second step of moving the magnet in a plane parallel with the sputtering target support surface to a second position different from the first position, in a state where a power is not applied to the cathode; and
a third step of generating a plasma by applying a power to the cathode and depositing a film on the substrate, while the magnet is kept still with respect to the sputtering target by being fixed at the second position in the cathode and the stage is moved in a second direction that is opposite to the first direction.

20. The film forming method according to claim 19, wherein the apparatus further includes a shield plate disposed between the sputtering target support surface and the substrate support surface.

21. The film forming method according to claim 20, wherein a slit-shaped opening portion, through which sputtered particles generated from the sputtering target can pass, is provided in the shield plate.

22. The film forming method according to claim 21, wherein
the shield plate is configured rotatable in a predetermined direction; and
the opening portion is an opening portion having a width in a direction perpendicular to a rotating direction of the shield plate larger than a width in the rotating direction.

23. The film forming method according to claim 20, wherein, in the first and third steps, at least one of the sputtering target support surface, the substrate support surface, and the shield plate is rotated so as to cause sputtered particles incident at a certain angle formed with a normal of the substrate support surface to enter the substrate supported by the substrate support surface, among the sputtered particles generated from the sputtering target supported by the sputtering target support surface.

24. A film forming method using an apparatus including a cathode having a sputtering target support surface for holding a sputtering target, a stage having a substrate support surface for holding a substrate, and a magnet disposed in the cathode, the method comprising:
a first step of generating a plasma by applying a power to the cathode and depositing a film on a first substrate, while the magnet is kept still with respect to the sputtering target by being fixed at a first position in the cathode and the stage is moved in a first direction;
a second step of moving the stage in a second direction that is opposite to the first direction, recovering the first substrate from the substrate support surface, arranging a second substrate on the substrate support surface, and moving the magnet in a plane parallel with the sputtering target support surface to a second position different from the first position, in a state where a power is not applied to the cathode; and
a third step of generating a plasma by applying a power to the cathode and depositing a film on the second substrate, while the magnet is kept still with respect to the sputtering target by being fixed at the second position in the cathode and the stage is moved in the first direction.

25. The film forming method according to claim 24, wherein the apparatus further includes a shield plate disposed between the sputtering target support surface and the substrate support surface.

26. The film forming method according to claim 25, wherein a slit-shaped opening portion, through which sputtered particles generated from the sputtering target can pass, is provided in the shield plate.

27. The film forming method according to claim 26, wherein
the shield plate is configured rotatable in a predetermined direction; and
the opening portion is an opening portion having a width in a direction perpendicular to a rotating direction of the shield plate larger than a width in the rotating direction.

28. The film forming method according to claim 25, wherein, in the first and third steps, at least one of the sputtering target support surface, the substrate support surface, and the shield plate is rotated so as to cause sputtered particles incident at a certain angle formed with a normal of the substrate support surface to enter the substrate supported by the substrate support surface, among the sputtered particles generated from the sputtering target supported by the sputtering target support surface.
